(19) United States
(12) Patent Application Publication
(10) Pub. No.: US 2016/0086819 A1
(43) Pub. Date: Mar. 24, 2016

(54) CMP POLISHING SOLUTION AND POLISHING METHOD USING SAME

(71) Applicant: HITACHI CHEMICAL COMPANY, LTD., Tokyo (JP)

(72) Inventors: Masahiro SAKASHITA, Chiyoda-ku, Tokyo (JP); Masayuki HANANO, Chiyoda-ku, Tokyo (JP); Kouji MISHIMA, Chiyoda-ku, Tokyo (JP)

(21) Appl. No.: 14/786,911

(22) PCT Filed: Apr. 24, 2014
(86) PCT No.: PCT/JP2014/061612

§ 371 Date: Oct. 23, 2015

(30) Foreign Application Priority Data
Apr. 25, 2013 (JP) 2013-092316
May 31, 2013 (JP) 2013-115360
Oct. 17, 2013 (JP) 2013-216230
Oct. 17, 2013 (JP) 2013-216232

(51) Int. Cl. H01L 21/321; C09G 1/02; H01L 23/532; H01L 21/285; H01L 21/768

(52) U.S. Cl. CPC H01L 21/3212; H01L 21/28556; H01L 21/28568; H01L 21/7685; H01L 21/7684; H01L 23/53238; C09G 1/02

(57) ABSTRACT

A CMP polishing liquid for polishing a ruthenium-based metal, comprising polishing particles, an acid component, an oxidizing agent, and water, wherein the acid component contains at least one selected from the group consisting of inorganic acids, monocarboxylic acids, carboxylic acids having a plurality of carboxyl groups and having no hydroxyl group, and salts thereof, the polishing particles have a negative zeta potential in the CMP polishing liquid, and the pH of the CMP polishing liquid is less than 7.0.

### TECHNICAL FIELD

The present invention relates to a CMP polishing liquid for polishing a ruthenium-based metal and a polishing method using the same.

### BACKGROUND ART

New microfabrication techniques have been developed recently with higher integration and enhanced performance of semiconductor integrated circuits (LSI). A chemical mechanical polishing (hereinafter, referred to as “CMP”) method is one of the techniques, which is frequently used in steps of manufacturing LSIs, particularly in planarization of interlayer insulating materials, formation of metal plugs, formation of embedded wirings, and the like in multilayer wiring forming steps.

Recently, a damascene method for forming damascene wirings is mainly used for increasing the integration of LSIs and enhancing the performance of LSIs. An example of the damascene method will be described using FIG. 1. First, trench portions (depressed portions) 2 are formed on the surface of an insulating material 1 (FIGS. 1(a) and 1(b)). Next, a wiring metal 3 is deposited to embed the trench portions 2 (FIG. 1(c)). At this time, as shown in FIG. 1(c), depressions and projections are formed on the surface of the wiring metal 3 due to influences of the depressions and projections of the insulating material 1. Finally, the wiring metal 3 excluding the part embedded in the trench portions 2 is removed by CMP (FIG. 1(d)).

As the wiring metal (metal for a wiring portion), copper-based metals (such as copper and copper alloys) are often used. The copper-based metal may be diffused into the insulating material. To prevent this diffusion, a barrier metal in the form of a layer is disposed between the copper-based metal and the insulating material. As the barrier metal, tantalum-based metals and titanium-based metals are used, for example. However, these barrier metals have low adhesion to the copper-based metal. For this reason, generally, a copper-based metal thin film called a seed layer (copper seed layer) is disposed, and a copper-based metal is deposited thereon, rather than directly forming a wiring portion on the barrier metal, to keep the adhesion between the copper-based metal and the barrier metal. Namely, as shown in FIG. 2, a substrate (base), including an insulating material 1 having depressed portions on the surface thereof, a barrier metal 4 disposed on the insulating material 1 so as to follow the shape of the surface of the insulating material 1, a seed layer 5 disposed on the barrier metal 4 so as to follow the shape of the barrier metal 4, and a wiring metal 3 disposed on the seed layer 5 so as to embed depressed portions and cover the entire surface of the seed layer, is used.

A physical vapor deposition method (hereinafter, referred to as the “PVD method”) may be used in formation of the barrier metal 4 and the seed layer 5. However, in the PVD method, it is likely that a metal (barrier metal or seed layer) 6 formed on the inner walls of the trench portions by the PVD method has a partially increased thickness in the vicinity of the openings of the trench portions (depressed portions) formed in an insulating material 1, as shown in FIG. 3(a). In this case, as microfabrication of the wiring is progressed, the metals disposed on the inner walls of the trench portion are in contact with each as shown in FIG. 3(b), remarkably generating hollows (voids) 7.

As a solution to this problem, approaches using a ruthenium-based metal having high adhesion to the copper-based metal have been examined. Namely, an approach using a ruthenium-based metal as a seed layer instead of a copper-based metal or an approach disposing a ruthenium-based metal between a seed layer using a copper-based metal and a barrier metal have been proposed. The ruthenium-based metal can be formed by a chemical vapor deposition method (hereinafter, referred to as the “CVD method”) or an atomic layer deposition method (hereinafter, referred to as the “ALD method”). The CVD method or the ALD method can readily prevent generation of hollows and can be used for formation of microwirings.

If the ruthenium-based metal is used, part of the ruthenium-based metal needs to be removed by CMP in the step of forming damascene wirings. In contrast, several methods of polishing noble metals have been proposed. For example, a method of polishing a noble metal such as platinum, iridium, ruthenium, rhenium, rhodium, palladium, silver, osmium, or gold using a polishing liquid comprising polishing particles and at least one additive selected from the group consisting of diketone, heterocyclic compounds, urea compounds, and amphoteric compounds has been proposed (for example, see Patent Literature 1 below). Moreover, a method of polishing a noble metal with a chemical mechanical polishing system comprising a polishing material, a liquid carrier, and a sulfonic compound or a salt thereof has been proposed (for example, see Patent Literature 2 below).

### CITATION LIST

### Patent Literature

Patent Literature 1: U.S. Pat. No. 6,527,622
Patent Literature 2: Japanese Unexamined Patent Application Publication No. 2006-519490

### SUMMARY OF INVENTION

### Technical Problem

However, it cannot be said that the CMP polishing liquid for polishing a ruthenium-based metal has been sufficiently examined. For this reason, it cannot also be said that evaluation methods on CMP for ruthenium-based metals are established. In the evaluation on CMP of the ruthenium-based metals so far, substrates having ruthenium-based metals formed thereon by the PVD method are used. However, the present inventor has found that polishing behaviors are different because of the states of the ruthenium-based metal are different according to the difference in methods of forming the ruthenium-based metal. Namely, compared to the ruthenium-based metal formed by the PVD method, the ruthenium-based metal formed by the CVD method or the ALD method is extremely difficult to remove by polishing, and the present inventor has found that the polishing rate differs more than several times in a polishing under the same condition.

As above, if the ruthenium-based metal is used to form a microwiring in the damascene step, the ruthenium-based metal needs to be formed by a method other than the PVD method (such as CVD method or ALD method). However, the conventional polishing liquid cannot achieve a high polishing rate in polishing of the ruthenium-based metal formed by a method other than the PVD method.

For this reason, a polishing liquid which can have a polishing rate without any problem in practice in polishing of the ruthenium-based metal formed by a method other than the PVD method (such as CVD method or ALD method) has been desired.

The present invention provides a CMP polishing liquid which can increase the polishing rate of a ruthenium-based metal compared to the cases where the conventional CMP polishing liquid is used, and a polishing method using the same.

### Solution to Problem

The present inventor, who has conducted extensive research, has found that the polishing rate of a ruthenium-based metal can be increased by use of a CMP polishing liquid comprising polishing particles having a negative zeta potential in the CMP polishing liquid, a specific acid component, an oxidizing agent, and water and having a pH of less than 7.0, compared to the cases where the conventional CMP polishing liquid is used, and has completed the present invention.

Namely, a first embodiment of the CMP polishing liquid according to the present invention is a CMP polishing liquid for polishing a ruthenium-based metal, comprising polishing particles, an acid component, an oxidizing agent, and water, wherein the acid component contains at least one selected from the group consisting of inorganic acids, monocarboxylic acids, carboxylic acids having a plurality of carboxyl groups and having no hydroxyl group, and salts thereof, the polishing particles have a negative zeta potential in the CMP polishing liquid, and the pH of the CMP polishing liquid is less than 7.0.

The CMP polishing liquid according to the first embodiment can increase the polishing rate of the ruthenium-based metal compared to the cases where the conventional CMP polishing liquid is used. It is inferred that such an effect can be attained for the following reason. Namely, it is inferred that in CMP of a ruthenium-based metal using the CMP polishing liquid according to the first embodiment, the acid component is reacted with the ruthenium-based metal to generate a ruthenium complex, and the polishing particles having a negative zeta potential in the CMP polishing liquid having a pH of less than 7.0 and the ruthenium-based metal electrostatically attract each other; thereby, the ruthenium-based metal can be polished at a high rate. For example, the CMP polishing liquid according to the first embodiment can increase the polishing rate of the ruthenium-based metal formed by the method other than the PVD method (such as CVD method or ALD method) compared to the cases where the conventional CMP polishing liquid is used. The CMP polishing liquid according to the first embodiment can also polish the ruthenium-based metal formed by the PVD method at a high polishing rate.

The CMP polishing liquid according to the first embodiment may further comprise a triazole-based compound. Thereby, the polishing rate of the ruthenium-based metal can be further increased.

It is preferred that the pH of the CMP polishing liquid according to the first embodiment be 1.0 to 6.0. Thereby, the polishing rate of the ruthenium-based metal can be further increased.

Furthermore, the present inventor has found the following knowledge. If a ruthenium-based metal is used in the damascene method, a wiring metal is exposed to the CMP polishing liquid during the step of removing the ruthenium-based metal by polishing. At this time, the CMP polishing liquid may comprise an oxidizing agent and/or the pH of the CMP polishing liquid may be low. In these cases, the wiring metal undergoes a galvanic attack (such as interfacial corrosion) by the ruthenium-based metal in the CMP polishing liquid due to the difference in standard oxidation/reduction potential between the ruthenium-based metal and the wiring metal in the CMP polishing liquid. Because such a galvanic attack occurs to etch the wiring metal (hereinafter, referred to as “galvanic corrosion” in some cases), the performance of the circuit is reduced. Because the galvanic corrosion causes a reduction in the performance of the circuit in this manner, it is preferred that the galvanic corrosion be prevented as much as possible.

For the galvanic corrosion, if two different metals electrically contacting each other are in contact with an electrolyte (for example, these are immersed in the electrolyte), these metals form a galvanic battery. A first metal forming an anode corrodes faster in the galvanic battery compared to the cases where a second metal forming a cathode is not present. In contrast, the second metal forming a cathode corrodes slower compared to the cases where the first metal forming an anode is not present. The force of promoting the corrosion process is the difference in potential between the two metals, specifically the difference in open-circuit potential (open circuit potential, corrosion potential) between the two metals in a specific electrolyte. If the two metals are in contact with the electrolyte to form a galvanic battery, it is known that a galvanic current generates due to the difference in potential between the two metals. The amount of the galvanic current is directly related with the rate of corrosion of the metal forming the anode (for example, a wiring metal such as a copper-based metal).

In contrast, the present inventor has found that in polishing of a base having a ruthenium-based metal and a wiring metal, if the difference in the open-circuit potential (difference in open circuit potential, difference in corrosion potential) of the ruthenium-based metal to the wiring metal in a CMP polishing liquid is −500 to 0 mV, the corrosion rate of the wiring metal caused by galvanic bond to the ruthenium-based metal is reduced to prevent the galvanic corrosion of the wiring metal by the CMP polishing liquid.

Furthermore, as a result of extensive research based on the above observation, the present inventor has found that if the difference A−B between the corrosion potential A of a ruthenium-based metal and the corrosion potential B of a wiring metal is small in a CMP polishing liquid comprising polishing particles having a negative zeta potential in the CMP polishing liquid, a specific acid component, and an oxidizing agent, the ruthenium-based metal can be polished at a high rate and the galvanic corrosion of the wiring metal can be prevented.

Namely, a second embodiment of the CMP polishing liquid according to the present invention is a CMP polishing liquid for polishing a base having a ruthenium-based metal and a wiring metal, comprising polishing particles, an acid component, an oxidizing agent, and water, wherein the acid component contains at least one selected from the group consisting of inorganic acids, monocarboxylic acids, carboxylic acids having a plurality of carboxyl groups and having no hydroxyl group, and salts thereof, the polishing particles have a negative zeta potential in the CMP polishing liquid, the difference A−B between the corrosion potential A of the ruthenium-based metal and the corrosion potential B of the wiring metal in the CMP polishing liquid is −500 to 0 mV, and the pH of the CMP polishing liquid is less than 7.0.

The CMP polishing liquid according to the second embodiment can increase the polishing rate of the ruthenium-based metal and prevent the galvanic corrosion of the wiring metal compared to the cases where the conventional CMP polishing liquid is used.

It is preferred that the CMP polishing liquid according to the second embodiment further comprise a first anti-corrosion agent represented by the following general formula (I). Thereby, the polishing rate of the ruthenium-based metal is readily increased and the galvanic corrosion of the wiring metal is readily prevented.

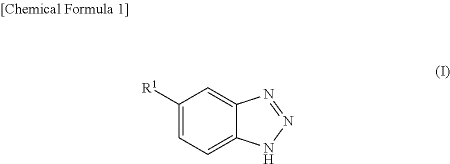

[In formula (I), R¹ represents a hydrogen atom or an alkyl group having 1 to 3 carbon atoms.]

It is preferred that the CMP polishing liquid according to the second embodiment further comprise a second anti-corrosion agent. Thereby, the polishing rate of the ruthenium-based metal can be further increased and the galvanic corrosion of the wiring metal can be more effectively prevented. From the same viewpoint, it is more preferred that the second anti-corrosion agent be a triazole-based compound (excluding the first anti-corrosion agent).

It is preferred that the CMP polishing liquid according to the second embodiment further comprise a quaternary phosphonium salt. Thereby, the polishing rate of the ruthenium-based metal is readily increased.

It is preferred that the quaternary phosphonium salt be at least one selected from the group consisting of triaryl phosphonium salts and tetraaryl phosphonium salts. Thereby, the polishing rate of the ruthenium-based metal is more readily increased.

It is preferred that the quaternary phosphonium salt be a compound represented by the following general formula (II). Thereby, the polishing rate of the ruthenium-based metal is more readily increased.

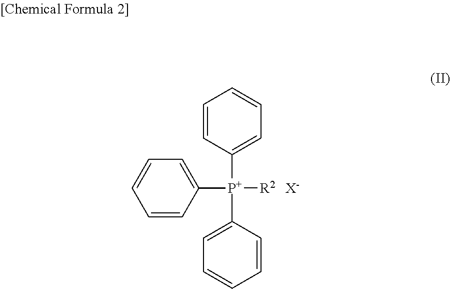

[In formula (II), benzene rings each may have a substituent; R² represents an optionally substituted alkyl or aryl group; and X⁻ represents an anion.]

It is preferred that the pH of the CMP polishing liquid according to the second embodiment be 3.5 or more. Thereby, the galvanic corrosion of the wiring metal can be further prevented.

It is preferred that the acid component be at least one selected from the group consisting of nitric acid, phosphoric acid, glycolic acid, lactic acid, glycine, alanine, salicylic acid, acetic acid, propionic acid, fumaric acid, itaconic acid, maleic acid, and salts thereof. Thereby, a practical polishing rate can be readily kept.

The CMP polishing liquid according to the present invention can be stored, transported, and used in the form of a plurality of separate liquids of components forming the CMP polishing liquid. Specifically, the CMP polishing liquid according to the present invention may be separately stored in the form of a first liquid and a second liquid, wherein the first liquid contains the polishing particles and the acid component, and the second liquid contains the oxidizing agent. Thereby, the oxidizing agent can be prevented from decomposing during storage and stable polishing properties can be attained.

The polishing method according to the present invention comprises a step of polishing a base having a ruthenium-based metal using the CMP polishing liquid to remove at least part of the ruthenium-based metal. Such a polishing method can increase the polishing rate of the ruthenium-based metal compared to the cases where the conventional CMP polishing liquid is used. For example, the polishing method according to the present invention can increase the polishing rate of the ruthenium-based metal formed by a method other than the PVD method (such as CVD method or ALD method) compared to the cases where the conventional CMP polishing liquid is used. Moreover, the polishing method according to the present invention can polish the ruthenium-based metal formed by the PVD method at a high polishing rate.

The base may further have a wiring metal. It is preferred that the wiring metal be a copper-based metal. Such a polishing method can sufficiently utilize the properties of the CMP polishing liquid to increase the polishing rate of the ruthenium-based metal. In particular, the polishing rate of the ruthenium-based metal can be increased and the galvanic corrosion of the copper-based metal can be prevented in the CMP polishing liquid according to the second embodiment.

The polishing method according to the present invention may further comprise a step of forming a ruthenium-based metal on a base by a formation method other than a PVD method to prepare a base having a ruthenium-based metal. The formation method may be at least one selected from the group consisting of CVD methods and ALD methods.

### Advantageous Effects of Invention

According to the present invention, at least the polishing rate of the ruthenium-based metal can be increased compared to the cases where the conventional CMP polishing liquid is used. For example, according to the present invention, the polishing rate of the ruthenium-based metal formed by a method other than the PVD method (such as CVD method or ALD method) can be increased compared to the cases where the conventional CMP polishing liquid is used. Moreover, according to the present invention, the ruthenium-based metal formed by the PVD method can also be polished at a high polishing rate. The present invention can provide applications (use) of the CMP polishing liquid to polishing of bases having ruthenium-based metals.

Moreover, one embodiment of the present invention can also provide a CMP polishing liquid which can increase at least the polishing rate of the ruthenium-based metal and prevent the galvanic corrosion of the wiring metal compared to the cases where the conventional CMP polishing liquid is used, and can provide a polishing method using the same. The present invention can provide applications (use) of the CMP polishing liquid to polishing of bases having ruthenium-based metals and wiring metals.

### BRIEF DESCRIPTION OF DRAWINGS

FIG. 1 is a schematic cross-sectional view illustrating a damascene method of forming damascene wirings.

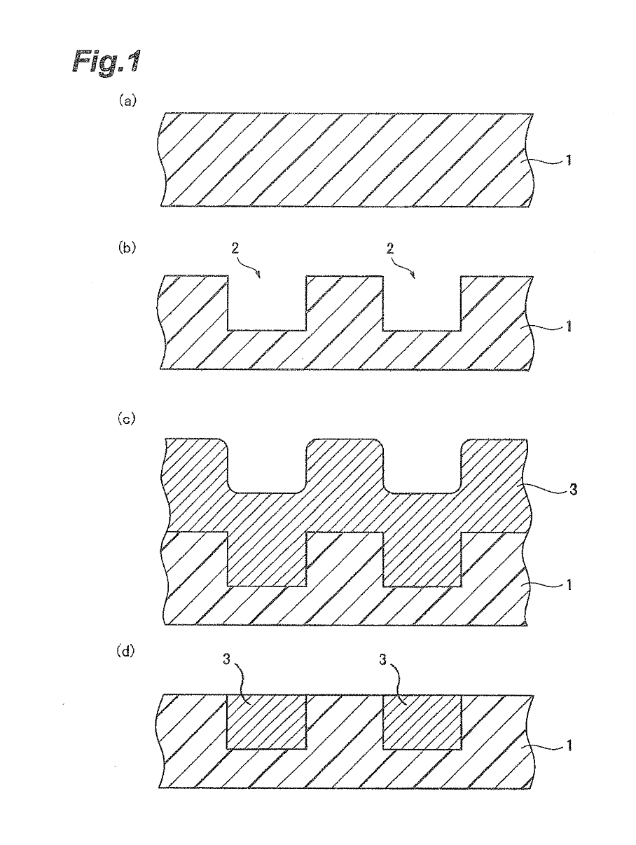

FIG. 2 is a schematic cross-sectional view illustrating a substrate having a seed layer disposed between a copper-based metal and a barrier metal.

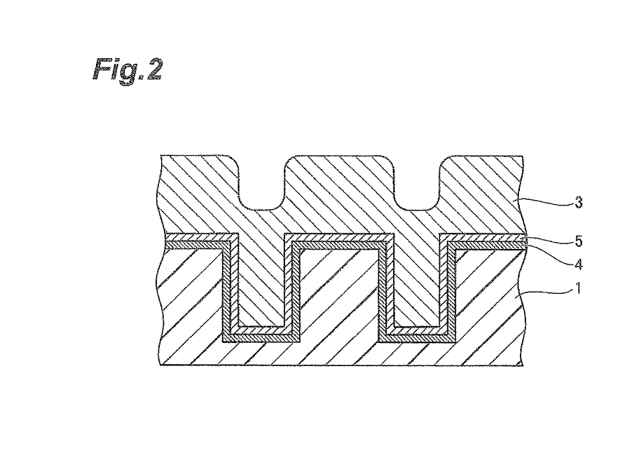

FIG. 3 is a schematic cross-sectional view illustrating a state of a metal formed by a PVD method.

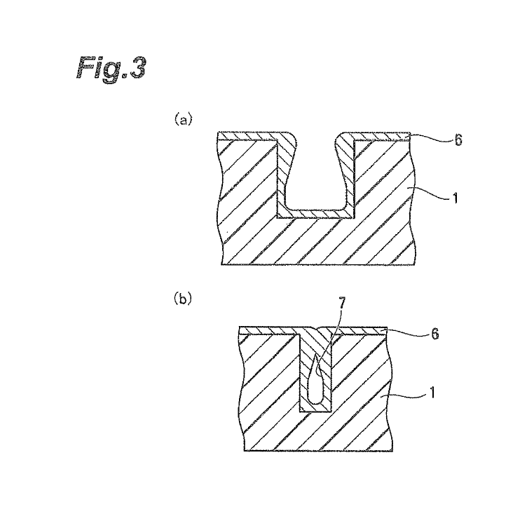

FIG. 4 is a schematic cross-sectional view illustrating a substrate having a ruthenium-based metal disposed instead of a copper seed layer.

FIG. 5 is a schematic cross-sectional view illustrating a substrate having a ruthenium-based metal disposed between a copper seed layer and a barrier metal.

FIG. 6 is a schematic cross-sectional view illustrating a step of polishing a base using a CMP polishing liquid.

### DESCRIPTION OF EMBODIMENTS

Embodiments of the present invention will hereinafter be described in detail. Throughout this specification, the numeric value range indicated using “to” indicates a range including numeric values written before and after “to” as the minimum value and the maximum value. Moreover, if a plurality of substances corresponding to a component in a composition is present, the content of the component in the composition indicates the total amount of the plurality of substances present in the composition, unless otherwise specified. The phrase “the present embodiment” involves the first embodiment and the second embodiment.

<CMP Polishing Liquid>

The CMP polishing liquid according to the first embodiment is a CMP polishing liquid for polishing a ruthenium-based metal. The CMP polishing liquid according to the first embodiment comprises (a) polishing particles (abrasive particles) having a negative zeta potential in the CMP polishing liquid, (b) an acid component containing at least one selected from the group consisting of inorganic acids, monocarboxylic acids, carboxylic acids having a plurality of carboxyl groups and having no hydroxyl group, and salts thereof, (c) an oxidizing agent, and (d) water, wherein the pH of the CMP polishing liquid is less than 7.0.

The CMP polishing liquid according to the second embodiment is a CMP polishing liquid for polishing a base having a ruthenium-based metal and a wiring metal. The CMP polishing liquid according to the second embodiment comprises (a) polishing particles (abrasive particles) having a negative zeta potential in the CMP polishing liquid, (b) an acid component containing at least one selected from the group consisting of inorganic acids, monocarboxylic acids, carboxylic acids having a plurality of carboxyl groups and having no hydroxyl group, and salts thereof, (c) an oxidizing agent, and (d) water. The difference A−B between the corrosion potential A of a ruthenium-based metal and the corrosion potential B of a wiring metal in the CMP polishing liquid according to the second embodiment is −500 to 0 mV. The pH of the CMP polishing liquid according to the second embodiment is less than 7.0.

The components forming the CMP polishing liquid and the like will hereinafter be described.

(Polishing Particles)

Generally, polishing particles have predetermined hardness, and therefore the mechanical action attributed to the hardness contributes to progression of polishing. The polishing particles used in the CMP polishing liquid according to the present embodiment have a negative (minus) zeta potential in the CMP polishing liquid having a pH of less than 7.0 (namely, zeta potential is less than 0 mV). Thereby, the polishing rate of the ruthenium-based metal is increased. Although the reason for this is not clear, it can be thought that the polishing particles having a negative zeta potential generate interaction between the polishing particles and the ruthenium-based metal due to electrostatic attraction to increase the polishing rate of the ruthenium-based metal.

From the viewpoint that such an effect is more significantly attained, the zeta potential is preferably −2 mV or less, more preferably −5 mV or less, further preferably −10 mV or less, particularly preferably −15 mV or less, extremely preferably −20 mV or less. From the viewpoint that the polishing particles repel each other to prevent aggregation of the polishing particles, it is preferred that the absolute value of the zeta potential be large (namely, separate from 0 mV).

The zeta potential can be measured with a product name DELSA NANO C manufactured by Beckman Coulter, Inc., for example. The zeta potential (ζ[mV]) can be measured according to the following procedure. First, the CMP polishing liquid is diluted with pure water such that the scattering intensity of the sample for measurement with a zeta potential measurement apparatus is 1.0×10⁴ to 5.0×10⁴ cps (where “cps” indicates counts per second, which is a unit of the number of particles counted), to obtain a sample. Then, the sample is placed in a cell for measuring the zeta potential to measure the zeta potential. To adjust the scattering intensity within the range, the CMP polishing liquid is diluted such that the content of the polishing particles is 1.7 to 1.8% by mass, for example.

The polishing particles are not limited in particular as long as the surface potential (zeta potential) in the CMP polishing liquid is negative; at least one selected from the group consisting of silica, alumina, zirconia, ceria, titania, germania, and modified products thereof is preferred.

Among the polishing particles, silica and alumina are preferred, colloidal silica and colloidal alumina are more preferred, and colloidal silica is further preferred from the viewpoint that the dispersion stability in the CMP polishing liquid is high and the number of polishing flaws (scratches) generated by CMP is small.

The zeta potential can vary according to the pH of the CMP polishing liquid described later. For this reason, if the polishing particles have a positive zeta potential in the CMP polishing liquid, the zeta potential of the polishing particles can be adjusted to be negative, for example, by applying a known method such as reforming of the surfaces of the polishing particles. Examples of such polishing particles include polishing particles of silica, alumina, zirconia, ceria, titania, or germania having their surfaces modified with a sulfo group or aluminate.

The upper limit of the average particle size of the polishing particles is preferably 200 nm or less, more preferably 100 nm or less, further preferably 80 nm or less from the viewpoint that the dispersion stability in the CMP polishing liquid is high and the number of polishing flaws generated by CMP is small. The lower limit of the average particle size of the polishing particles is not limited in particular; it is preferably 1 nm or more. Moreover, the lower limit of the average particle size of the polishing particles is more preferably 10 nm or more, further preferably 20 nm or more, particularly preferably 30 nm or more, extremely preferably 40 nm or more from the viewpoint that the polishing rate of the ruthenium-based metal is readily increased.

The “average particle size” of the polishing particles indicates the average secondary particle diameter of the polishing particles. The average particle size indicates the D50 value (median size in volume distribution, cumulative median value) determined by measuring the CMP polishing liquid with a dynamic light scattering particle size distribution analyzer (such as product name COULTER N4 SD manufactured by COULTER Electronics, Inc.).

Specifically, the average particle size can be measured according to the following procedure. First, about 100 μL (L represents litter. The same is true below) of the CMP polishing liquid is weighed, and is diluted with deionized water such that the content of the polishing particles is around 0.05% by mass (where transmittance (H) is 60 to 70% in measurement of the content) to obtain a diluted liquid. The diluted liquid is then placed in a sample tank of the dynamic light scattering particle size distribution analyzer, and the value displayed as D50 is read to measure the average particle size.

The content of the polishing particles is preferably 1.0% by mass or more, more preferably 5.0% by mass or more, further preferably 10.0% by mass or more based on the total mass of the CMP polishing liquid from the viewpoint that a favorable polishing rate of the ruthenium-based metal is readily attained. The content of the polishing particles is preferably 50.0% by mass or less, more preferably 30.0% by mass or less, further preferably 20.0% by mass or less based on total mass of the CMP polishing liquid from the viewpoint that the generation of polishing flaws is readily prevented.

(Acid Component)

The CMP polishing liquid according to the present embodiment comprises an acid component containing at least one selected from the group consisting of inorganic acid components (such as inorganic acids and inorganic acid salts) and organic acid components (such as organic acids and organic acid salts), specifically comprises an acid component containing at least one selected from the group consisting of inorganic acids, monocarboxylic acids (carboxylic acids having one carboxyl group), carboxylic acids having a plurality of carboxyl groups and having no hydroxyl group, and salts thereof to increase the polishing rate of the ruthenium-based metal. It can be thought that the specific acid component is reacted with the ruthenium-based metal to form a complex, and therefore, a high polishing rate of the ruthenium-based metal can be attained. If the base to be polished has a barrier metal other than the ruthenium-based metal, a wiring metal, and the like, the specific acid component can also increase the polishing rates of these metals.

Examples of the inorganic acid components include nitric acid, phosphoric acid, hydrochloric acid, sulfuric acid, chromic acid, and salts thereof. As the inorganic acid components, at least one selected from the group consisting of nitric acid, phosphoric acid, and salts thereof is preferred, nitric acid, phosphoric acid, and phosphates are more preferred, nitric acid and phosphoric acid are further preferred, and phosphoric acid is particularly preferred from the viewpoint that a practical polishing rate is readily kept. Examples of the inorganic acid salts include ammonium salts. Examples of ammonium salts include ammonium nitrate, ammonium phosphate, ammonium chloride, and ammonium sulfate.

The organic acid component can be a compound corresponding to any of monocarboxylic acid, carboxylic acids having a plurality of carboxyl groups and having no hydroxyl group, and salts thereof, and may be any of hydroxy acid, carboxylic acid (such as monocarboxylic acid and dicarboxylic acid), amino acid, a pyran compound, a ketone compound, and the like. As the organic acid component, at least one selected from the group consisting of hydroxy acids, monocarboxylic acids, and dicarboxylic acids is preferred, and hydroxy acids are more preferred from the viewpoint that a practical polishing rate is readily kept. Moreover, the organic acid component may be any of saturated carboxylic acids, unsaturated carboxylic acids, aromatic carboxylic acids, and the like.

Examples of the monocarboxylic acids include glycolic acid, lactic acid, glycine, alanine, salicylic acid, formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, and glyceric acid. Examples of the carboxylic acids having a plurality of carboxyl groups and having no hydroxyl group include fumaric acid, itaconic acid, maleic acid, oxalic acid, malonic acid, succinic acid, glutaric acid, adipic acid, pimelic acid, and phthalic acid. Examples of the organic acid salts include ammonium salts. Examples of the ammonium salts include ammonium acetate.

As the organic acid component, from the viewpoint that a practical polishing rate is readily kept, at least one selected from the group consisting of glycolic acid, lactic acid, glycine, alanine, salicylic acid, acetic acid, propionic acid, fumaric acid, itaconic acid, maleic acid, and salts thereof is preferred, and at least one hydroxy acid selected from the group consisting of glycolic acid, lactic acid, and salicylic acid is more preferred.

As the acid component, at least one selected from the group consisting of nitric acid, phosphoric acid, glycolic acid, lactic acid, glycine, alanine, salicylic acid, acetic acid, propionic acid, fumaric acid, itaconic acid, maleic acid, and salts thereof is preferred from the viewpoint that a practical polishing rate is readily kept.

The acid component may be used singly or in combinations of two or more.

In the first embodiment, the content of the acid component is preferably 0.01% by mass or more, more preferably 0.5% by mass or more, further preferably 1.0% by mass or more, particularly preferably 1.5% by mass or more based on the total mass of the CMP polishing liquid from the viewpoint that the polishing rate of the ruthenium-based metal is readily increased. From the same viewpoint and from the viewpoint that high stability of the polishing liquid is attained, in the first embodiment, the content of the acid component is preferably 20.0% by mass or less, more preferably 3.0% by mass or less, further preferably 2.0% by mass or less based on the total mass of the CMP polishing liquid.

In the second embodiment, the content of the acid component is preferably 0.01% by mass or more, more preferably 0.1% by mass or more, further preferably 0.2% by mass or more, particularly preferably 0.3% by mass or more based on the total mass of the CMP polishing liquid from the viewpoint that the polishing rate of the ruthenium-based metal is readily increased. From the same viewpoint and from the viewpoint that high stability of the polishing liquid is attained, in the second embodiment, the content of the acid component is preferably 1.0% by mass or less, more preferably 0.7% by mass or less, further preferably 0.5% by mass or less based on the total mass of the CMP polishing liquid.

(Oxidizing Agent)

The CMP polishing liquid according to the present embodiment comprises an oxidizing agent for a metal (hereinafter simply referred to as “oxidizing agent”). As the oxidizing agent, a compound corresponding to the acid component above is excluded.

Examples of the oxidizing agent include, but should not be limited to, hydrogen peroxide, hypochlorous acid, ozone water, periodic acid, periodates, iodates, bromates, persulfates, and cerium nitrate salts. From the viewpoint that the ruthenium moiety of the ruthenium-based metal is oxidized in an acidic solution to become trivalent, and therefore, the polishing rate of the ruthenium-based metal is further increased, hydrogen peroxide is preferred as the oxidizing agent. Hydrogen peroxide may be used in the form of a hydrogen peroxide solution. Examples of salts such as periodates, iodates, bromates, persulfates, and cerium nitrates include ammonium salts. The oxidizing agent may be used singly or in combinations of two or more.

The content of the oxidizing agent is preferably 0.001% by mass or more, more preferably 0.005% by mass or more, further preferably 0.01% by mass or more, particularly preferably 0.02% by mass or more, extremely preferably 0.03% by mass or more based on the total mass of the CMP polishing liquid from the viewpoint that the polishing rate of the ruthenium-based metal is further increased. The content of the oxidizing agent is preferably 50.0% by mass or less, more preferably 5.0% by mass or less, further preferably 1.0% by mass or less, particularly preferably 0.5% by mass or less, extremely preferably 0.1% by mass or less based on the total mass of the CMP polishing liquid from the viewpoint that the surface roughness is unlikely to be generated after polishing. For oxidizing agents usually available in the form of an aqueous solution, such as hydrogen peroxide solutions, the content of the oxidizing agent contained in the aqueous solution can be adjusted within the range above in the CMP polishing liquid.

(Triazole-Based Compound)

The CMP polishing liquid according to the first embodiment can further comprise a triazole-based compound to further increase the polishing rate of the ruthenium-based metal. Although factors to attain such effects are not always clear, it is inferred that, when the CMP polishing liquid comprises the triazole-based compound, nitrogen atoms (N atoms) in the triazole-based compound are coordinated with the ruthenium-based metal to form a weak reaction layer, and therefore, the polishing rate of the ruthenium-based metal is further increased. Moreover, the triazole-based compound also has an effect to prevent the etching of the wiring metal. As the triazole-based compound, compounds known as anti-corrosion agents or protective film forming agents can be used without limitation.

Examples of the triazole-based compound include, but should not be limited to, compounds having skeletons such as 1,2,3-triazole, 1,2,4-triazole, 3-amino-1H-1,2,4-triazole, 1-hydroxybenzotriazole, 1-hydroxypropylbenzotriazole, 2,3-dicarboxypropylbenzotriazole, 4-hydroxybenzotriazole, 4-carboxyl(-1H-)benzotriazole, 4-carboxyl(-1H-)benzotriazole methyl ester, 4-carboxyl(-1H-)benzotriazole butyl ester, 4-carboxyl(-1H-)benzotriazole octyl ester, 5-hexylbenzotriazole, [1,2,3-benzotriazolyl-1-methyl][1,2,4-triazolyl-1-methyl][2-ethylhexyl]amine, benzotriazole, 5-methyl(-1H-)benzotriazole (another name: tolyltriazole), 5-ethyl(-1H-)benzotriazole, 5-propyl(-1H-)benzotriazole, naphthotriazole, and bis[(1-benzotriazolyl)methyl]phosphonic acid. The triazole-based compound may be used singly or in combinations of two or more.

As the triazole-based compound, a compound represented by the following general formula (I) is preferred. Thereby, the polishing rate of the ruthenium-based metal is further increased. Although factors to attain such effects are not always clear, it is inferred that the compound represented by the general formula (I) is readily coordinated with the ruthenium-based metal among the triazole-based compounds, and therefore, the polishing rate of the ruthenium-based metal can be increased. Examples of the compound represented by the general formula (I) include benzotriazole, 5-methyl(-1H-)benzotriazole, 5-ethyl(-1H-)benzotriazole, and 5-propyl(-1H-)benzotriazole.

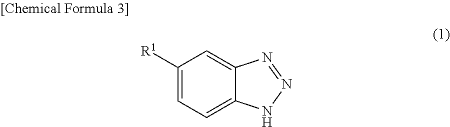

[In formula (I), R¹ represents a hydrogen atom or an alkyl group having 1 to 3 carbon atoms.]

Moreover, as the triazole-based compound, 1,2,4-triazole is preferred from the viewpoint that the polishing rate of the ruthenium-based metal is further increased. Use of the compound represented by the general formula (I) in combination with 1,2,4-triazole further increases the polishing rate of the ruthenium-based metal. Namely, in the CMP polishing liquid according to the first embodiment, use of the compound represented by the general formula (I) in combination with 1,2,4-triazole is preferred. Although factors to attain such effects are not always clear, it is inferred that, because 1,2,4-triazole is a compound readily coordinated with the ruthenium-based metal and readily dissolved in water among the triazole-based compounds, the ruthenium-based metal complex is more readily formed by use of the compound represented by the general formula (I) in combination with 1,2,4-triazole compared to the cases where these compounds are singly used, so that the polishing rate of the ruthenium-based metal can be increased. In particular, the polishing rate of the ruthenium-based metal can be further increased by use of 1,2,4-triazole in combination with 5-methyl(-1H-)benzotriazole compared to the cases where the triazole-based compound is singly used.

The content of the compound represented by the general formula (I) is preferably 0.001% by mass or more, more preferably 0.01% by mass or more, further preferably 0.1% by mass or more, particularly preferably 0.2% by mass or more, extremely preferably 0.3% by mass or more based on the total mass of the CMP polishing liquid from the viewpoint that the polishing rate of the ruthenium-based metal is readily increased. Moreover, from the same viewpoint, the content of the compound represented by the general formula (I) is preferably 10.0% by mass or less, more preferably 5.0% by mass or less, further preferably 2.0% by mass or less, particularly preferably 1.0% by mass or less based on the total mass of the CMP polishing liquid.

The content of the triazole-based compound is preferably 0.001% by mass or more, more preferably 0.01% by mass or more, further preferably 0.1% by mass or more based on the total mass of the CMP polishing liquid from the viewpoint that the polishing rate of the ruthenium-based metal is readily increased. The content of the triazole-based compound is preferably 30.0% by mass or less, more preferably 10.0% by mass or less, further preferably 5.0% by mass or less based on the total mass of the CMP polishing liquid from the viewpoint that a reduction in the polishing rate of the ruthenium-based metal is readily prevented. If a plurality of compounds is used as the triazole-based compound, it is preferred that the total content of the compounds satisfy the range.

(Anti-Corrosion Agent)

It is preferred that the CMP polishing liquid according to the second embodiment comprise a compound represented by the following general formula (I) as a first anti-corrosion agent. Thereby, the polishing rate of the ruthenium-based metal is readily increased and the galvanic corrosion of the wiring metal is readily prevented. Although factors to attain such effects are not always clear, it is inferred that the compound represented by the general formula (I) is readily coordinated with the ruthenium-based metal, and therefore, the galvanic corrosion can be prevented while increasing the polishing rate of the ruthenium-based metal. Examples of the first anti-corrosion agent include benzotriazole, 5-methyl(-1H-)benzotriazole, 5-ethyl(-1H-)benzotriazole, and 5-propyl(-1H-)benzotriazole.

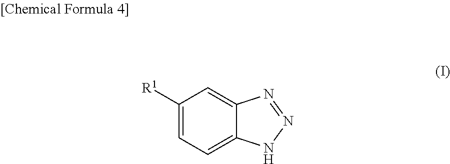

[In formula (I), R¹ represents a hydrogen atom or an alkyl group having 1 to 3 carbon atoms.]

The content of the first anti-corrosion agent is preferably 0.001% by mass or more, more preferably 0.01% by mass or more, further preferably 0.1% by mass or more, particularly preferably 0.2% by mass or more, extremely preferably 0.3% by mass or more based on the total mass of the CMP polishing liquid from the viewpoint that the etching of the wiring metal is readily prevented to be unlikely to generate roughness of the polished surface. The content of the first anti-corrosion agent is preferably 10.0% by mass or less, more preferably 5.0% by mass or less, further preferably 2.0% by mass or less, particularly preferably 1.0% by mass or less based on the total mass of the CMP polishing liquid from the viewpoint that the polishing rates of the wiring metal and the barrier metal are unlikely to be reduced.

It is preferred that the CMP polishing liquid according to the second embodiment comprise a second anti-corrosion agent different from the first anti-corrosion agent to readily increase the polishing rate of the ruthenium-based metal and more effectively prevent the galvanic corrosion of the wiring metal. As the second anti-corrosion agent, compounds known as anti-corrosion agents or protective film forming agents can be used without limitation; among these, triazole-based compounds (excluding the first anti-corrosion agent) are preferred. It is inferred that if the CMP polishing liquid comprises a triazole-based compound, nitrogen atoms (N atoms) in the triazole-based compound are coordinated with the ruthenium-based metal to form a reaction layer, which is weak but bearable to the galvanic corrosion, and therefore, the galvanic corrosion can be prevented while increasing the polishing rate of the ruthenium-based metal.

Examples of the triazole-based compound include, but should not be limited to, compounds having skeletons such as 1,2,3-triazole, 1,2,4-triazole, 3-amino-1H-1,2,4-triazole, 1-hydroxybenzotriazole, 1-hydroxypropylbenzotriazole, 2,3-dicarboxypropylbenzotriazole, 4-hydroxybenzotriazole, 4-carboxyl(-1H-)benzotriazole, 4-carboxyl(-1H-)benzotriazole methyl ester, 4-carboxyl(-1H-)benzotriazole butyl ester, 4-carboxyl(-1H-)benzotriazole octyl ester, 5-hexylbenzotriazole, [1,2,3-benzotriazolyl-1-methyl][1,2,4-triazolyl-1-methyl][2-ethylhexyl]amine, naphthotriazole, and bis[(1-benzotriazolyl)methyl]phosphonic acid.

Among the triazole-based compounds, 1,2,4-triazole is preferred. Use of 1,2,4-triazole in combination with the first anti-corrosion agent further increases the polishing rate of the ruthenium-based metal. Namely, in the CMP polishing liquid according to the second embodiment, use of 1,2,4-triazole in combination with the first anti-corrosion agent is preferred. Although factors to attain such effects are not always clear, it is inferred that because 1,2,4-triazole is a compound readily coordinated with the ruthenium-based metal and readily dissolved in water among the triazole-based compounds, the ruthenium-based metal complex is more readily formed by use of 1,2,4-triazole in combination with the first anti-corrosion agent compared to the cases where these compounds are singly used, so that the polishing rate of the ruthenium-based metal can be increased. For example, the polishing rate of the ruthenium-based metal can be further increased by use of 1,2,4-triazole in combination with 5-methyl(-1H-)benzotriazole compared to the cases where the triazole-based compounds are singly used.

The anti-corrosion agent may be used singly or in combinations of two or more. As the anti-corrosion agent, the second anti-corrosion agent may be used singly.

The content of the second anti-corrosion agent is preferably 0.001% by mass or more, more preferably 0.01% by mass or more, further preferably 0.1% by mass or more based on the total mass of the CMP polishing liquid from the viewpoint that the polishing rate of the ruthenium-based metal is further increased. The content of the second anti-corrosion agent is preferably 30.0% by mass or less, more preferably 10.0% by mass or less, further preferably 5.0% by mass or less based on the total mass of the CMP polishing liquid from the viewpoint that a reduction in the polishing rate of the ruthenium-based metal is readily prevented.

(Quaternary Phosphonium Salt)

It is preferred that the CMP polishing liquid according to the second embodiment further comprise a quaternary phosphonium salt from the viewpoint that the polishing rate of the ruthenium-based metal is readily increased. As the quaternary phosphonium salt, at least one selected from the group consisting of triarylphosphonium salts and tetraarylphosphonium salts is preferred, and tetraarylphosphonium salts are more preferred from the viewpoint that the polishing rate of the ruthenium-based metal is more readily increased.

Examples of substituents bonded to the phosphorus atom of the quaternary phosphonium salt include an aryl group, an alkyl group, and a vinyl group.

Examples of the aryl group bonded to the phosphorus atom include a phenyl group, a benzyl group, and a naphthyl group; a phenyl group is preferred.

The alkyl group bonded to the phosphorus atom may be a linear alkyl group or a branched alkyl group. For the chain length of the alkyl group, the following range is preferred based on the number of carbon atoms from the viewpoint that the polishing rate of ruthenium is further increased. The number of carbon atoms of the alkyl group is preferably 1 or more, more preferably 4 or more. The number of carbon atoms of the alkyl group is preferably 14 or less, more preferably 7 or less. If the number of carbon atoms of the alkyl group is 14 or less, the CMP polishing liquid tends to have high storage stability. The chain length is determined from the portion having the longest chain length.

Substituent such as a halogen group, a hydroxy group (hydroxyl group), a nitro group, a cyano group, an alkoxy group, a formyl group, an amino group (such as an alkylamino group), a naphthyl group, an alkoxy carbonyl group, and a carboxy group may be further bonded to the substituent bonded to the phosphorus atom. For example, an aryl group having a substituent may be a 2-hydroxybenzyl group, a 2-chlorobenzyl group, a 4-chlorobenzyl group, a 2,4-dichlorobenzyl group, a 4-nitrobenzyl group, a 4-ethoxybenzyl group, and a 1-naphthylmethyl group. The alkyl group having a substituent may be a cyanomethyl group, a methoxymethyl group, a formylmethyl group, a methoxycarbonylmethyl group, an ethoxycarbonylmethyl group, a 3-carboxypropyl group, a 4-carboxybutyl group, a 2-dimethylaminoethyl group, or the like. If the alkyl group is branched, a portion branched from the longest chain (portion not having the longest chain length) is defined as the substituent.

Examples of counter anions (negative ions) of quaternary phosphonium cations of the quaternary phosphonium salts include, but should not be limited to, halogen ions (such as F⁻, Cl⁻, Br⁻, and I⁻), hydroxide ions, nitrate ions, nitrite ions, hypochlorite ions, chlorite ions, chlorate ions, perchlorate ions, acetate ions, hydrogen carbonate ions, phosphate ions, sulfate ions, hydrogen sulfate ions, sulfite ions, thiosulfate ions, and carbonate ions.

As the triarylphosphonium salts, alkyltriarylphosphonium salts (compounds having an alkyltriarylphosphonium salt structure) are preferred, and alkyltriphenylphosphonium salts are more preferred from the viewpoint that the polishing rate of ruthenium is further increased.

It is thought that a quaternary phosphonium salt having a long-chain alkyl group instead of an aryl group as the substituent bonded to the phosphorus atom is used to enhance hydrophobicity. However, as a result of research by the present inventor, it is verified that, in a cases using such quaternary phosphonium salts, an effect of increasing the polishing rate of ruthenium may be small and bubbling of the CMP polishing liquid may occur.

For the chain length of the alkyl group of the alkyltriarylphosphonium salt, the above range based on the number of carbon atoms is preferred from the viewpoint that the polishing rate of ruthenium is further increased.

As the quaternary phosphonium salt, a compound represented by the following general formula (II) is preferred.

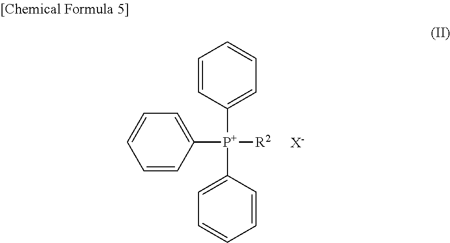

[In formula (II), benzene rings each may have a substituent; R² represents an optionally substituted alkyl or aryl group; and X⁻represents an anion.]

Examples of the alkyl group and the aryl group of R² in the formula (II) include the alkyl groups and aryl groups described above. As the alkyl group for R², alkyl groups having 14 or less carbon atoms are preferred from the viewpoint of high stability of the polishing liquid. Examples of the aryl group for R² include, but should not be limited to, a phenyl group and a methylphenyl group.

As the anion X⁻ in the formula (II), the counter anions described above as the counter anions of the quaternary phosphonium cations can be used. The anion X⁻ is not limited in particular; halogen ions are preferred, and bromonium ions are more preferred.

Specific examples of the quaternary phosphonium salt include methyltriphenylphosphonium salts, ethyltriphenylphosphonium salts, triphenylpropylphosphonium salts, isopropyltriphenylphosphonium salts, butyltriphenylphosphonium salts, pentyltriphenylphosphonium salts, hexyltriphenylphosphonium salts, n-heptyltriphenylphosphonium salts, triphenyl(tetradecyl)phosphonium salts, tetraphenylphosphonium salts, benzyltriphenylphosphonium salts, (2-hydroxybenzyl)triphenylphosphonium salts, (2-chlorobenzyl)triphenylphosphonium salts, (4-chlorobenzyl)triphenylphosphonium salts, (2,4-dichlorobenzyl)phenylphosphonium salts, (4-nitrobenzyl)triphenylphosphonium salts, 4-ethoxybenzyltriphenylphosphonium salts, (1-naphthylmethyl)triphenylphosphonium salts, (cyanomethyl)triphenylphosphonium salts, (methoxymethyl)triphenylphosphonium salts, (formylmethyl)triphenylphosphonium salts, acetonyltriphenylphosphonium salts, phenacyltriphenylphosphonium salts, methoxycarbonylmethyl(triphenyl)phosphonium salts, ethoxycarbonylmethyl(triphenyl)phosphonium salts, (3-carboxypropyl)triphenylphosphonium salts, (4-carboxybutyl)triphenylphosphonium salts, 2-dimethylaminoethyltriphenylphosphonium salts, triphenylvinylphosphonium salts, allyltriphenylphosphonium salts, and triphenylpropargylphosphonium salts. The quaternary phosphonium salt may be used singly or in combinations of two or more.

Among these, butyltriphenylphosphonium salts, pentyltriphenylphosphonium salts, hexyltriphenylphosphonium salts, n-heptyltriphenylphosphonium salts, tetraphenylphosphonium salts, and benzyltriphenylphosphonium salts are preferred from the viewpoint of high affinities for the wiring metal. As the salts thereof, bromonium salts and chloride salts are preferred.

The content of the quaternary phosphonium salt is preferably 0.0001% by mass or more, more preferably 0.001% by mass or more, further preferably 0.005% by mass or more based on the total mass of the CMP polishing liquid from the viewpoint that the effect of increasing the polishing rate of ruthenium is effectively attained. The content of the quaternary phosphonium salt is preferably 0.1% by mass or less, more preferably 0.05% by mass or less, further preferably 0.01% by mass or less based on the total mass of the CMP polishing liquid from the viewpoint that the polishing rate of ruthenium is further increased and the CMP polishing liquid has high storage stability.

(Metal Solubilizing Agent)

The CMP polishing liquid according to the present embodiment can further comprise a metal solubilizing agent to increase the polishing rate of a metal material such as a barrier metal other than the ruthenium-based metal, and a wiring metal. Any compound reactive with the metal material to form a complex can be used as the metal solubilizing agent without limitation, however, compounds corresponding to the acid component above are excluded. Examples of the metal solubilizing agent include organic acids such as malic acid, tartaric acid, and citric acid; organic acid esters of these organic acids; and ammonium salts of these organic acids.

Among these, preferred are malic acid, tartaric acid, and citric acid from the viewpoint that a practical CMP rate can be kept and excessive etching of the wiring metal is readily prevented. The metal solubilizing agent can be used singly or in combinations of two or more.

The content of the metal solubilizing agent is preferably 0.001% by mass or more, more preferably 0.01% by mass or more, further preferably 0.1% by mass or more based on the total mass of the CMP polishing liquid from the viewpoint of increasing the polishing rate of the metal material such as a barrier metal other than the ruthenium-based metal, and a wiring metal. The content of the metal solubilizing agent is preferably 20.0% by mass or less, more preferably 10.0% by mass or less, further preferably 5.0% by mass or less based on the total mass of the CMP polishing liquid from the viewpoint that etching is readily prevented and roughness of the polished surface is unlikely to be generated.

(Metal Anti-Corrosion Agent)

The CMP polishing liquid according to the present embodiment can further comprise a metal anti-corrosion agent (excluding the triazole-based compound) to prevent excessive polishing of the metal material such as a barrier metal other than the ruthenium-based metal, and a wiring metal.

Examples of the metal anti-corrosion agent include, but should not be limited to, compounds having a thiazole skeleton, compounds having a pyrimidine skeleton, compounds having a tetrazole skeleton, compounds having an imidazole skeleton, and compounds having a pyrazole skeleton.

Examples of the compounds having a thiazole skeleton include 2-mercaptobenzothiazole.

Examples of the compounds having a pyrimidine skeleton include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetoamidepyrimidine, 2-aminopyrimidine, 2-methyl-5,7-diphenyl-(1,2,4)triazolo[1,5-a]pyrimidine, 2-methylsulfanyl-5,7-diphenyl-(1,2,4)triazolo[1,5-a]pyrimidine, 2-methylsulfanyl-5,7-diphenyl-4,7-dihydro-(1,2,4)triazolo[1,5-a]pyrimidine, and 4-aminopyrazolo[3,4-d]pyrimidine.

Examples of the compounds having a tetrazole skeleton include tetrazole, 5-methyltetrazole, 5-aminotetrazole, and 1-(2-dimethylaminoethyl)-5-mercaptotetrazole.

Examples of the compounds having an imidazole skeleton include imidazole, 2-methylimidazole, 2-ethylimidazole, 2-isopropylimidazole, 2-propylimidazole, 2-butylimidazole, 4-methylimidazole, 2,4-dimethylimidazole, 2-ethyl-4-methylimidazole, 2-undecylimidazole, and 2-aminoimidazole.

Examples of the compounds having a pyrazole skeleton include pyrazole, 3,5-dimethylpyrazole, 3-amino-5-methylpyrazole, 4-methylpyrazole, and 3-amino-5-hydroxypyrazole.

The metal anti-corrosion agent can be used singly or in combinations of two or more.

The content of the metal anti-corrosion agent is preferably 0.001% by mass or more, more preferably 0.005% by mass or more, further preferably 0.01% by mass or more based on the total mass of the CMP polishing liquid from the viewpoint that excessive etching of the wiring metal is readily prevented and roughness of the polished surface is unlikely to be generated. The content of the metal anti-corrosion agent is preferably 10.0% by mass or less, more preferably 5.0% by mass or less, further preferably 2.0% by mass or less based on the total mass of the CMP polishing liquid from the viewpoint that the polishing rate of the wiring metal and the barrier metal is unlikely to be reduced.

(Water-Soluble Polymer)

The CMP polishing liquid according to the present embodiment can further comprise a water-soluble polymer. If the CMP polishing liquid comprises a water-soluble polymer, the exchange current density in the presence of a load can be increased and the exchange current density in the absence of a load can be reduced. This principle has not been clarified yet.

Examples of the water-soluble polymers include, but should not be limited to, polycarboxylic acids and salts thereof, such as poly(aspartic acid), poly(glutamic acid), polylysine, poly(malic acid), poly(methacrylic acid), ammonium polymethacrylate, sodium polymethacrylate, poly(amic acid), poly(maleic acid), poly(itaconic acid), poly(fumaric acid), poly(p-styrene carboxylate), poly(acrylic acid), poly(acrylamide), aminopoly(acrylamide), ammonium polyacrylate, sodium polyacrylate, polyamic acid ammonium salt, polyamic acid sodium salt, and poly(glyoxylic acid); polysaccharides, such as alginic acid, pectic acid, carboxy methyl cellulose, agar, curdlan, and pullulan; and vinyl-based polymers, such as poly(vinyl alcohol), poly(vinylpyrrolidone), poly-(4-vinylpyridine), and polyacrolein. The water-soluble polymer may be used singly or in combinations of two or more.

The lower limit of the weight average molecular weight of the water-soluble polymer is preferably 500 or more, more preferably 1500 or more, further preferably 5000 or more. At a weight average molecular weight of the water-soluble polymer of 500 or more, a high polishing rate of the barrier metal is readily attained. The weight average molecular weight of the water-soluble polymer can have any upper limit, and is preferably 5000000 or less from the viewpoint of high solubility. The weight average molecular weight of the water-soluble polymer can be measured under the following conditions by gel permeation chromatography (GPC) using calibration curves of standard polystyrenes.

<GPC Conditions>

Sample: 10 μL

Standard polystyrenes: manufactured by Tosoh Corporation, standard polystyrenes (molecular weight: 190000, 17900, 9100, 2980, 578, 474, 370, and 266)

Detector: manufactured by Hitachi, Ltd., RI-monitor, product name “L-3000”

Integrator: manufactured by Hitachi, Ltd., GPC integrator, product name “D-2200”

Pump: manufactured by Hitachi, Ltd., product name “L-6000”

Degassing apparatus: manufactured by Showa Denko K.K., product name “Shodex DEGAS” (“Shodex” is a registered trademark)

Columns: manufactured by Hitachi Chemical Company, Ltd., product names “GL-R440,” “GL-R430,” and “GL-R420” are connected in this order for use

Eluent: tetrahydrofuran (THF)

Temperature for measurement: 23° C.

Flow rate: 1.75 mL/min

Measurement time: 45 minutes

The content of the water-soluble polymer is preferably 0.001% by mass or more, more preferably 0.005% by mass or more, further preferably 0.01% by mass or more based on the total mass of the CMP polishing liquid. The content of the water-soluble polymer is preferably 15.0% by mass or less, more preferably 10.0% by mass or less, further preferably 5.0% by mass or less based on the total mass of the CMP polishing liquid from the viewpoint that the stability of the polishing particles contained in the CMP polishing liquid is sufficiently kept.

(Organic Solvent)

The CMP polishing liquid according to the present embodiment can further comprise an organic solvent. Thereby, the wettability of the CMP polishing liquid on the base such as substrates can be enhanced to increase the polishing rate of the barrier metal other than the ruthenium-based metal, or the like. Any organic solvent can be used without limitation; solvents which can be arbitrarily mixed with water are preferred.

Specific examples of the organic solvents include carbonate esters such as ethylene carbonate, propylene carbonate, dimethyl carbonate, diethyl carbonate, and methylethyl carbonate; lactones such as butyrolactone and propiolactone; glycols such as ethylene glycol, propylene glycol, diethylene glycol, dipropylene glycol, triethylene glycol, and tripropylene glycol; derivatives of glycols such as glycol monoethers such as ethylene glycol monomethyl ether, propylene glycol monomethyl ether, diethylene glycol monomethyl ether, dipropylene glycol monomethyl ether, triethylene glycol monomethyl ether, tripropylene glycol monomethyl ether, ethylene glycol monoethyl ether, propylene glycol monoethyl ether, diethylene glycol monoethyl ether, dipropylene glycol monoethyl ether, triethylene glycol monoethyl ether, tripropylene glycol monoethyl ether, ethylene glycol monopropyl ether, propylene glycol monopropyl ether, diethylene glycol monopropyl ether, dipropylene glycol monopropyl ether, triethylene glycol monopropyl ether, tripropylene glycol monopropyl ether, ethylene glycol monobutyl ether, propylene glycol monobutyl ether, diethylene glycol monobutyl ether, dipropylene glycol monobutyl ether, triethylene glycol monobutyl ether, and tripropylene glycol monobutyl ether, and glycol diethers such as ethylene glycol dimethyl ether, propylene glycol dimethyl ether, diethylene glycol dimethyl ether, dipropylene glycol dimethyl ether, triethylene glycol dimethyl ether, tripropylene glycol dimethyl ether, ethylene glycol diethyl ether, propylene glycol diethyl ether, diethylene glycol diethyl ether, dipropylene glycol diethyl ether, triethylene glycol diethyl ether, tripropylene glycol diethyl ether, ethylene glycol dipropyl ether, propylene glycol dipropyl ether, diethylene glycol dipropyl ether, dipropylene glycol dipropyl ether, triethylene glycol dipropyl ether, tripropylene glycol dipropyl ether, ethylene glycol dibutyl ether, propylene glycol dibutyl ether, diethylene glycol dibutyl ether, dipropylene glycol dibutyl ether, triethylene glycol dibutyl ether, and tripropylene glycol dibutyl ether; ethers such as tetrahydrofuran, dioxane, dimethoxyethane, poly(ethylene oxide), ethylene glycol monomethyl acetate, diethylene glycol monoethyl ether acetate, and propylene glycol monomethyl ether acetate; alcohols such as methanol, ethanol, propanol, n-butanol, n-pentanol, n-hexanol, and isopropanol; ketones such as acetone and methyl ethyl ketone; phenols; amides such as dimethyl formamide; n-methylpyrrolidone; ethyl acetate; ethyl lactate; and sulfolanes. Among these, carbonate esters, glycol monoethers, and alcohols are preferred. The organic solvent may be used singly or in combinations of two or more.

The content of the organic solvent is preferably 0.1% by mass or more, more preferably 0.2% by mass or more, further preferably 0.5% by mass or more based on the total mass of the CMP polishing liquid from the viewpoint that the wettability of the CMP polishing liquid on the base such as substrates is sufficiently ensured. The content of the organic solvent is preferably 50.0% by mass or less, more preferably 30.0% by mass or less, further preferably 10.0% by mass or less based on the total mass of the CMP polishing liquid from the viewpoint that dispersibility is sufficiently ensured.

(Surfactant)

The CMP polishing liquid according to the present embodiment can further comprise a surfactant. Examples of the surfactant include water-soluble anionic surfactants such as lauryl ammonium sulfate and polyoxyethylene lauryl ether ammonium sulfate; and water-soluble non-ionic surfactants such as polyoxyethylene lauryl ether and polyethylene glycol monostearate. Among these, water-soluble anionic surfactants are preferred as a surfactant. In particular, at least one water-soluble anionic surfactant such as polymer dispersants obtained by using ammonium salts as a copolymerizable component is more preferred. The water-soluble non-ionic surfactant, water-soluble anionic surfactant, water-soluble cationic surfactant, and the like may be used in combination. The content of the surfactant is, for example, 0.0001 to 0.1% by mass based on the total mass of the CMP polishing liquid.

(Water)

The CMP polishing liquid according to the present embodiment comprises water. The content of water in the CMP polishing liquid may be the rest other than the content of other constitutional components of the polishing liquid.

(pH of CMP Polishing Liquid)

The pH of the CMP polishing liquid according to the first embodiment is less than 7.0 from the viewpoint that the polishing rate of the ruthenium-based metal is increased by the electrostatic attracting action between the polishing particles and the ruthenium-based metal. The pH of the CMP polishing liquid is preferably 6.0 or less, more preferably 5.8 or less, further preferably 5.5 or less, particularly preferably 5.0 or less, extremely preferably 4.0 or less from the viewpoint that a higher polishing rate of the ruthenium-based metal is attained. The pH of the CMP polishing liquid is preferably 1.0 or more, more preferably 2.0 or more, further preferably 2.5 or more from the viewpoint that the safety in use is high. Any known pH adjuster such as acids and bases can be used to adjust the pH. The pH is defined as a pH at a liquid temperature of 25° C.

The pH of the CMP polishing liquid according to the second embodiment is less than 7.0 from the viewpoint that the polishing rate of the ruthenium-based metal is increased by the electrostatic attracting action between the polishing particles and the ruthenium-based metal. The pH of the CMP polishing liquid is preferably 6.0 or less, more preferably 5.8 or less, further preferably 5.5 or less from the viewpoint that a higher polishing rate of the ruthenium-based metal is attained. The pH of the CMP polishing liquid is preferably 2.0 or more, more preferably 3.0 or more, further preferably 3.5 or more, particularly preferably 4.0 or more, extremely preferably 4.3 or more from the viewpoint that the galvanic corrosion of the wiring metal is further prevented. Any known pH adjuster such as acids and bases can be used to adjust the pH. The pH is defined as a pH at a liquid temperature of 25° C.

The pH of the CMP polishing liquid can be measured with a pH meter (for example, manufactured by Denki Kagaku Keiki K.K., Model No. PHL-40). For example, the pH of the CMP polishing liquid can be measured by placing an electrode in the CMP polishing liquid and measuring a value stabilized after a lapse of 2 minutes or more at 25° C., after performing two-point calibration using standard buffer solutions (phthalate pH buffer, pH: 4.01 (25° C.); neutral phosphate pH buffer, pH: 6.86 (25° C.)).

(Difference in Corrosion Potential)

In the CMP polishing liquid according to the second embodiment, the difference A−B between the corrosion potential A of the ruthenium-based metal and the corrosion potential B of the wiring metal in the CMP polishing liquid is −500 to 0 mV. Thereby, the galvanic corrosion of the wiring metal caused by the ruthenium-based metal can be prevented.

It is preferred that the difference A−B in corrosion potential be closer to 0 mV from the viewpoint that the galvanic corrosion is prevented. In contrast, it is preferred that the difference A−B in corrosion potential be closer to −500 mV from the viewpoint that the polishing rate of the ruthenium-based metal is increased. Considering the balance between these viewpoints, the difference A−B in corrosion potential is more preferably −350 to 0 mV, further preferably −300 to 0 mV, particularly preferably −300 to −100 mV.

The corrosion potential can be obtained, for example, by immersing a reference electrode containing a ruthenium-based metal or a wiring metal, a silver/silver chloride electrode (action electrode), and a platinum electrode (counter electrodes) in the CMP polishing liquid, and measuring the corrosion electrode of the reference electrode with an “electrochemical measuring system HZ-5000” manufactured by HOKUTO DENKO CORPORATION. The difference A−B in corrosion potential can be adjusted, for example, by the contents of the components in the CMP polishing liquid.

The CMP polishing liquid according to the present embodiment can be stored, transported, and used in the form of a plurality of separate liquids of components forming the CMP polishing liquid. For example, the CMP polishing liquid according to the present embodiment may be separately stored as a component containing an oxidizing agent and constitutional components other than the oxidizing agent, or may be separately stored in the form of a first liquid and a second liquid, wherein the first liquid contains the polishing particles and the acid component, and the second liquid contains the oxidizing agent. In the first embodiment, the first liquid may further contain a triazole compound, a metal solubilizing agent, a metal anti-corrosion agent, a water-soluble polymer, an organic solvent, a surfactant, and the like. In the second embodiment, the first liquid may further contain an anti-corrosion agent (such as the triazole-based compound and the metal anti-corrosion agent above), quaternary phosphonium salts, a metal solubilizing agent, a water-soluble polymer, an organic solvent, a surfactant, and the like.

<Polishing Method>

Next, the polishing method according to the present embodiment will be described.

The polishing method according to the first embodiment comprises a polishing step of polishing a base having a ruthenium-based metal using the CMP polishing liquid to remove at least part of the ruthenium-based metal. The polishing method according to the second embodiment comprises a polishing step of polishing a base having a ruthenium-based metal and a wiring metal using the CMP polishing liquid to remove at least part of the ruthenium-based metal. In the polishing step, for example, the CMP polishing liquid is fed between the surface to be polished of the base having a ruthenium-based metal and a polishing pad (polishing cloth) to remove at least part of the ruthenium-based metal.

If the base has a ruthenium-based metal and a wiring metal and the ruthenium-based metal and the wiring metal are exposed on the surface to be polished of the base, the base may be polished using the CMP polishing liquid in the polishing step to remove at least part of the ruthenium-based metal and at least part of the wiring metal.

The base to be polished using the CMP polishing liquid is a base having a ruthenium-based metal. The base may further have a wiring metal. The ruthenium-based metal is in the form of a layer (layer containing a ruthenium-based metal), for example. Examples of the base include substrates such as semiconductor substrates; parts such as parts for airplanes and automobiles; cars such as train cars; and housings for electronic apparatuses.

The polishing method according to the present embodiment may further comprise a step of forming a ruthenium-based metal on a base (first base) to prepare a base having a ruthenium-based metal (second base). The base having a ruthenium-based metal may further have a wiring metal. As the method of forming a ruthenium-based metal, a method other than the PVD method is preferred, at least one method selected from the group consisting of CVD methods and ALD methods is more preferred, and a CVD method is further preferred. Thereby, if the microwiring (for example, wiring width: 15 nm or less) is formed, hollows generated in the wiring portion can be further prevented, and the ruthenium-based metal is readily removed at a favorable polishing rate if polished using the CMP polishing liquid according to the present embodiment.

Hereinafter, using an example in which the base is a semiconductor substrate, the polishing method according to the present embodiment will be described in detail. Examples using a ruthenium-based metal, in the cases where the base is a semiconductor substrate, include a step of forming damascene wiring.

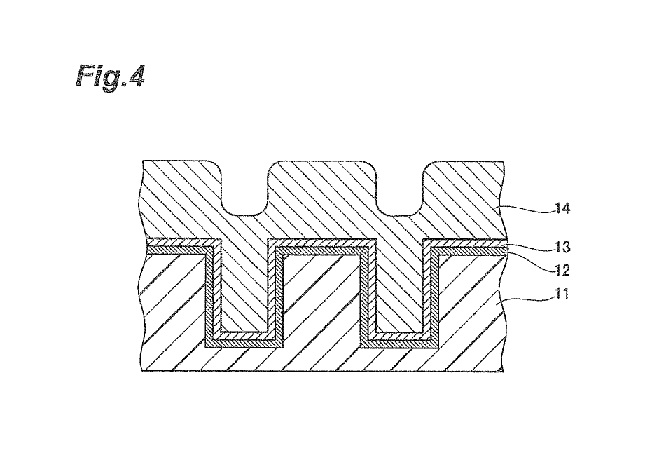

Examples include a method using a ruthenium-based metal as a seed layer instead of a copper seed layer, as illustrated in FIG. 4. In FIG. 4, reference sign 11 illustrates an insulating material, reference sign 12 illustrates a barrier metal, reference sign 13 illustrates a ruthenium-based metal, and reference sign 14 illustrates a wiring metal. The semiconductor substrate illustrated in FIG. 4 can be obtained, for example, by forming trench portions (depressed portions) on the surface of the insulating material 11, forming the barrier metal 12 on the insulating material 11 so as to follow the shape of the surface of the insulating material 11, then forming the ruthenium-based metal 13 on the barrier metal 12 so as to follow the shape of the barrier metal 12, and finally forming the wiring metal 14 on the ruthenium-based metal 13 so as to embed depressed portions and cover the entire surface thereof.

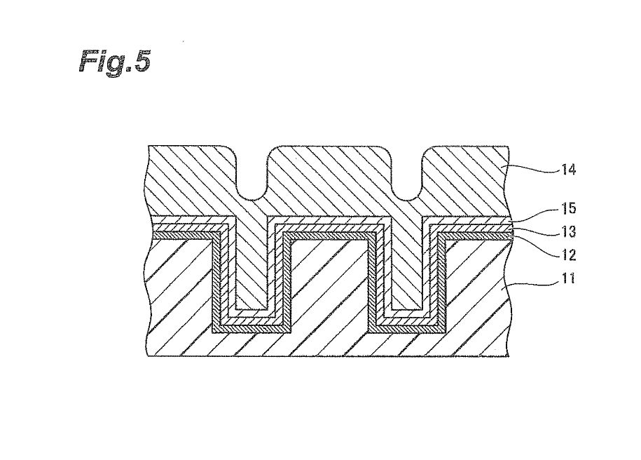

Moreover, examples include a method disposing a ruthenium-based metal 13 between a barrier metal 12 and a seed layer 15 using the same metal material as that for a wiring metal 14, as illustrated in FIG. 5. Namely, a step of forming the seed layer 15 using the same metal material as that for the wiring metal 14 is added after formation of the ruthenium-based metal 13 in FIG. 4 to obtain a semiconductor substrate having a structure illustrated in FIG. 5.

As the wiring metal, copper-based metals such as copper, copper alloys, copper oxides, and copper alloy oxides are preferred. The wiring metal can be formed by a known method such as sputtering or plating.

Examples of the ruthenium-based metal include ruthenium, ruthenium alloys (such as alloys containing more than 50% by mass of ruthenium), and ruthenium compounds. Examples of the ruthenium alloys include ruthenium tantalum alloys and ruthenium titanium alloys. Examples of the ruthenium compounds include ruthenium nitride.

The barrier metal is formed to prevent diffusion of the wiring metal to the insulating material. Examples of the barrier metal include, but should not be limited to, tantalum-based metals such as tantalum, tantalum alloys, tantalum compounds (such as tantalum nitride); titanium-based metals such as titanium, titanium alloys, and titanium compounds (such as titanium nitride); and tungsten-based metals such as tungsten, tungsten alloys, and tungsten compounds (such as tungsten nitride).

Any insulating material which can reduce the parasitic capacitance between elements or between wirings and has insulation properties can be used without limitation; examples thereof include inorganic materials such as SiO₂, SiOF, and Si—H containing SiO₂; organic inorganic hybrid materials such as carbon-containing SiO₂ (SiOC) and methyl group-containing SiO₂; and organic polymer materials such as fluorinated resin-based polymers (such as PTFE-based polymers), polyimide-based polymers, poly(arylether)-based polymers, and parylene-based polymers.

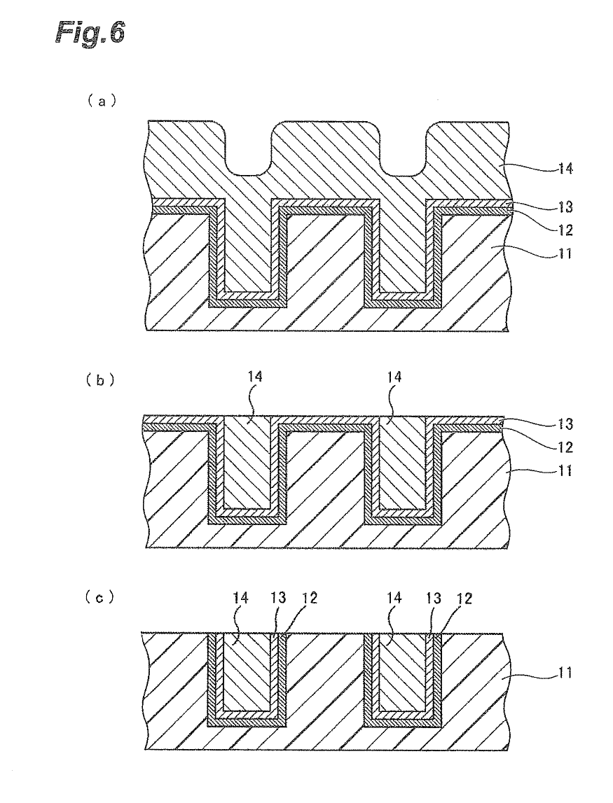

The step of polishing a base using the CMP polishing liquid according to the present embodiment will be described by way of FIG. 6. In FIG. 6, reference sign 11 illustrates an insulating material, reference sign 12 illustrates a barrier metal, reference sign 13 illustrates a ruthenium-based metal, and reference sign 14 illustrates a wiring metal. FIG. 6(a) is a cross-sectional view illustrating the state of a substrate before polishing, FIG. 6(b) is a cross-sectional view illustrating the state of the substrate after a first polishing step, and FIG. 6(c) is a cross-sectional view illustrating the state of the substrate after a second polishing step.

First, the wiring metal 14 is polished using a CMP polishing liquid for a wiring metal to expose the ruthenium-based metal 13 present on the projecting portions of the insulating material 11, to obtain a substrate having a structure illustrated in FIG. 6(b) (first polishing step). Next, the ruthenium-based metal 13 and the barrier metal 12 present on the projecting portions of the insulating material 11 and part of the wiring metal 14 present in depressed portions of the insulating material 11 are polished to expose the projecting portions of the insulating material 11, to obtain a substrate illustrated in FIG. 6(c) (second polishing step). Of these two polishing steps, it is preferred that the CMP polishing liquid according to the present embodiment be used at least in the second polishing step. Moreover, to enhance flatness, the polishing may be continued (overpolished) for a predetermined time after the insulating material 11 is exposed in the second polishing step. Namely, in the polishing step in the present embodiment, the base may be polished using the CMP polishing liquid to remove at least part of the ruthenium-based metal, at least part of the wiring metal, and at least part of the insulating material.

For example, a typical polishing apparatus having a platen to which a polishing pad can be attached and a holder for holding a substrate can be used as a polishing apparatus. A motor whose number of rotations can be varied or the like may be attached to the platen. Any polishing pad can be used without limitation; typical non-woven fabrics, foamed polyurethane, porous fluorinated resin, and the like can be used. Any polishing condition can be used without limitation; it is preferred that the rotational speed of the platen be adjusted to a low number of rotations of 200 min⁻¹ or less such that the substrate does not fall out of the platen.

The pressure applied to the substrate pressed against the polishing pad (polishing pressure) is preferably 4 to 100 kPa, more preferably 6 to 50 kPa from the viewpoint that high in-plane uniformity in the substrate and high flatness of the pattern are attained. By using the CMP polishing liquid according to the present embodiment, the ruthenium-based metal can be polished at a high polishing rate under a low polishing pressure. Attaining polishing at a low polishing pressure is preferred from the viewpoint that peel off, chipping, fragmentation, cracking, and the like of the polished material are prevented and high flatness of the pattern is attained.

It is preferred that the CMP polishing liquid be continuously fed to the polishing pad with a pump or the like during polishing Any amount of the CMP polishing liquid can be fed without limitation; it is preferred that the surface of the polishing pad be always covered with the polishing liquid. After polishing is over, it is preferred that the substrate be sufficiently washed with running water, water droplets adhering to the substrate be shaken off using a spin dryer or the like, and the substrate be dried.

### Examples

Hereinafter, the present invention will be described in more detail by way of Examples, but the present invention will not be limited to these Examples without departing from the technical ideas of the present invention. For example, the type and the compounding ratio of the materials for the polishing liquid may be the type and the compounding ratio other than those described in Examples, and the composition and structure of the object to be polished may be the composition and the structure other than those described in Examples.

<Method of Preparing Polishing Liquid>

Polishing liquids were prepared using components shown in Tables 1 to Table 4 by the following method.

### Example A1

3.0 parts by mass of colloidal silica having an average secondary particle size of 60 nm and having a surface modified with a sulfo group, 1.7 parts by mass of phosphoric acid, 0.03 parts by mass of hydrogen peroxide, and water were mixed with stirring to prepare 100 parts by mass of a CMP polishing liquid. The amounts of the colloidal silica, the phosphoric acid, and the hydrogen peroxide to be added were adjusted using a colloidal silica liquid containing 20% by mass of silica particles, an 85% by mass phosphoric acid aqueous solution, and a 30% by mass hydrogen peroxide solution.

### Examples A2 to A13

Components shown in Table 1 were mixed, and the operation was performed in the same manner as in Example A1 to prepare CMP polishing liquids in Examples A2 to A13. As anionic colloidal silica, colloidal silica having an average secondary particle size of 60 nm and having a surface modified with a sulfo group was used.

(Comparative Examples A1 to A7)

Components shown in Table 2 were mixed, and the operation was performed in the same manner as in Example A1 to prepare CMP polishing liquids in Comparative Examples A1 to A7. As cationic colloidal silica, colloidal silica having an average secondary particle size of 60 nm and being cationic at a pH of 1 to 5 was used. As anionic colloidal silica, colloidal silica having an average secondary particle size of 60 nm and having a surface modified with a sulfo group was used.

### Example B1

15.0 parts by mass of colloidal silica having an average secondary particle size of 60 nm and having a surface modified with a sulfo group, 0.4 parts by mass of phosphoric acid, 0.03 parts by mass of hydrogen peroxide, 0.5 parts by mass of 5-methyl(-1H-)benzotriazole, 3.0 parts by mass of 1,2,4-triazole, and water were mixed, and the pH was adjusted to the value shown in Table 3 with aqueous ammonia to prepare 100 parts by mass of a CMP polishing liquid (CMP polishing liquid in Example B1). The amounts of the colloidal silica, the phosphoric acid, and the hydrogen peroxide to be added were adjusted using a colloidal silica liquid containing 20% by mass of silica particles, an 85% by mass phosphoric acid aqueous solution, and a 30% by mass hydrogen peroxide solution.

### Examples B2 to B14 and Comparative Examples B1 to B2

Components shown in Table 3 were mixed, and the operation was performed in the same manner as in Example B1 to prepare CMP polishing liquids in Examples B2 to B14 and CMP polishing liquids in Comparative Examples B1 and B2. The CMP polishing liquid in Example B13 is the same as that in Example A9. The CMP polishing liquid in Example B14 is the same as that in Example A8. As anionic colloidal silica, colloidal silica having an average secondary particle size of 60 nm and having a surface modified with a sulfo group was used. As cationic colloidal silica, colloidal silica having an average secondary particle size of 60 nm and being cationic at a pH of 1 to 5 was used.

### Examples C1 to C10 and Comparative Examples C1 to C3

Components shown in Table 4 were mixed, and the operation was performed in the same manner as in Example A1 to prepare CMP polishing liquids in Examples C1 to C10 and CMP polishing liquids in Comparative Examples C1 to C3. As anionic colloidal silica, colloidal silica having an average secondary particle size of 60 nm and having a surface modified with a sulfo group was used.

<Evaluation on Properties of Polishing Liquids>

The zeta potential of the polishing particles in the CMP polishing liquid and the pH of the CMP polishing liquid were determined by the following procedures and conditions. The results of measurement are as shown in Table 1 to Table 4.

(Zeta Potential)

The zeta potential of the colloidal silica in the CMP polishing liquid was measured with “DELSA NANO C” manufactured by Beckman Coulter, Inc.

(pH)

Temperature for measurement: 25±5° C.

Measuring apparatus: manufactured by Denki Kagaku Keiki K.K., Model No. PHL-40

<Evaluation on Polishing Properties>

Examples and Comparative Examples were evaluated for the following items.

(1. Evaluation on Polishing of Ruthenium-Based Metal)

### [Substrate to be Polished]

A ruthenium blanket substrate comprising a ruthenium film having a thickness of 15 nm (150 Å) formed on a silicon substrate by a CVD method was prepared.

[Polishing a of Base]

The bases to be polished were subjected to CMP using the CMP polishing liquids in Examples A1 to A13, Examples C1 to C10, Comparative Examples A1 to A7, and Comparative Examples C1 to C3 for 60 seconds under the following polishing conditions.

Polishing apparatus: polishing machine for one-sided metal film (manufactured by Applied Materials, Inc., product name: MIRRA (“MIRRA” is a registered trademark))

Polishing pad: polishing pad made of a foamed polyurethane resin

The number of rotations of platen: 93 min⁻¹

The number of rotations of head: 87 min⁻¹

Polishing pressure: 14 kPa

The amount of polishing liquid to be fed: 200 mL/min

[Polishing B of base]

The bases to be polished were subjected to CMP using the CMP polishing liquids in Examples B1 to B14 and Comparative Examples B1 and B2 for 60 seconds under the following polishing conditions.

Polishing apparatus: polishing machine for one-sided metal film (manufactured by Applied Materials, Inc., product name: Reflexion LK)

Polishing pad: polishing pad made of a foamed polyurethane resin

The number of rotations of platen: 123 min⁻¹

The number of rotations of head: 117 min⁻¹

Polishing pressure: 10.3 kPa (1.5 psi)

The amount of polishing liquid to be fed: 300 mL/min

[Washing of Base]

After a sponge brush (made of a poly(vinyl alcohol)-based resin) was pressed against the polished surface of the substrate polished above, the substrate was washed for 60 seconds by rotating the substrate and the sponge brush while feeding distilled water to the substrate. Next, after the sponge brush was removed, distilled water was fed to the polished surface of the substrate for 60 seconds. Finally, the substrate was rotated at a high speed to shake off distilled water from the substrate to dry the substrate.

[Evaluation on Polishing Rate]

The polishing rate was evaluated as follows. Based on the difference in film thickness before and after polishing measured with a metal film thickness measurement apparatus (product name: VR-120/08S) manufactured by Hitachi Kokusai Electric Inc., the polishing rate of the ruthenium blanket substrate polished and washed under the above conditions was determined. The results of measurement are shown in Table 1 to Table 4 as “Ruthenium polishing rate.”

(2. Evaluation on Polishing Flaw)

The substrate after CMP (ruthenium blanket substrate in (1. Evaluation on polishing of ruthenium-based metal)) was observed visually and with an optical microscope and an electron microscope to verify the presence of the generation of polishing flaws. As a result, generation of remarkable polishing flaws was not found in all of Examples and Comparative Examples.

(3. Evaluation on Influences on Wiring Metal)

The measurement of corrosion potential and the evaluation on the galvanic corrosion of wiring metals were performed using the CMP polishing liquids in Examples B1 to B14, Examples C1 to C10, Comparatives Example B1 and B2, and Comparative Examples C1 to C3.

(3-1. Measurement of Corrosion Potential)

The corrosion potential A of a ruthenium-based metal and the corrosion potential B of a wiring metal were measured with an “electrochemical measuring system HZ-5000” manufactured by HOKUTO DENKO CORPORATION, and the difference A−B in corrosion potential was determined. Namely, a reference electrode was prepared by cutting a blanket wafer having a film for measurement of potential on the surface into an appropriate size, a silver/silver chloride electrode was prepared as an action electrode, and a platinum electrode was prepared as a counter electrode. These three electrodes were placed in the CMP polishing liquid, and the difference in potential was determined by measurement mode: linear sweep voltammetry. The results of measurement are shown in Table 3 and Table 4 as “Corrosion potential [Ru—Cu].”

(3-2. Evaluation on Galvanic Corrosion of Wiring Metal)

### [Preparation of Patterned Substrate (Base to be Polished)]

The following substrate was prepared as a base. A copper film other than depressed portions (trench portions) of a patterned substrate having a size of diameter of 12 inches (30.5 cm) (φ) with a copper wiring (manufactured by Advanced Materials Technology, Inc., SEMATECH 754 CMP pattern: interlayer insulation film made of silicon dioxide and having a thickness of 3000 Å: having a pattern of a copper wiring width of 180 nm and a wiring density of 50%) was polished using a polishing liquid for a copper film by a known CMP method to expose the barrier layer at projecting portions to the polished surface. The patterned substrate was cut into small pieces of 2 cm×2 cm, and was used in the following polishing. The barrier layer of the patterned substrate was a tantalum film having a thickness of 300 Å.

[Polishing of Base]

The bases to be polished were subjected to CMP for 60 seconds using the CMP polishing liquids in Examples B1 to B14, Examples C1 to C10, Comparative Examples B1 and B2, and Comparative Examples C1 to C3 under the above polishing conditions.

[Evaluation on Galvanic Corrosion]

The galvanic corrosion of the patterned substrates after polishing was evaluated under the following conditions. Namely, the copper wiring portion having a copper wiring width of 180 nm and a wiring density of 50% in the patterned substrates after polishing was observed with a Review SEM observing apparatus, SEM vision G3 manufactured by Applied Materials Technology, Inc. Cases where galvanic corrosion was not found at all were evaluated as good, and were written as “A” in the tables. Cases where galvanic corrosion was found were written as “B” in the tables. The results of evaluation are shown in Table 3 and Table 4.

TABLE 1

| | | Zeta | | | Triazole- | Triazole- | | | Ruthe- |
|---|---|---|---|---|---|---|---|---|---|
| | Polishing | potential | | Oxidizing | based | based | | | nium |
| | particles | of polishing | | agent | compound | compound | | | polishing |
| | (% by | particles | Acid | (% by | (1) (% by | (2) (% by | pH | | rate |
| No. | mass) | (mV) | (% by mass) | mass) | mass) | mass) | adjuster | pH | (Å/min) |
| Example | Anionic | −5 | Phosphoric | Hydrogen | — | — | — | 1.5 | 40 |
| A1 | colloidal | | acid | peroxide | | | | | |
| | silica | | (1.7) | (0.03) | | | | | |
| | (3.0) | | | | | | | | |
| Example | Anionic | −5 | Phosphoric | Hydrogen | — | — | — | 1.5 | 50 |
| A2 | colloidal | | acid | peroxide | | | | | |
| | silica | | (1.7) | (0.03) | | | | | |
| | (5.0) | | | | | | | | |
| Example | Anionic | −5 | Phosphoric | Hydrogen | — | — | — | 1.5 | 80 |
| A3 | colloidal | | acid | peroxide | | | | | |
| | silica | | (1.7) | (0.03) | | | | | |
| | (15.0) | | | | | | | | |
| Example | Anionic | −15 | Phosphoric | Hydrogen | — | — | — | 3.0 | 40 |
| A4 | colloidal | | acid | peroxide | | | | | |
| | silica | | (0.1) | (0.03) | | | | | |
| | (15.0) | | | | | | | | |
| Example | Anionic | −8 | Phosphoric | Hydrogen | — | — | — | 2.2 | 60 |
| A5 | colloidal | | acid | peroxide | | | | | |
| | silica | | (0.5) | (0.03) | | | | | |
| | (15.0) | | | | | | | | |
| Example | Anionic | −2 | Phosphoric | Hydrogen | — | — | — | 1.2 | 60 |
| A6 | colloidal | | acid | peroxide | | | | | |
| | silica | | (3.0) | (0.03) | | | | | |
| | (15.0) | | | | | | | | |
| Example | Anionic | −5 | Nitric | Hydrogen | — | — | — | 1.5 | 60 |
| A7 | colloidal | | acid | peroxide | | | | | |
| | silica | | (1.7) | (0.03) | | | | | |
| | (15.0) | | | | | | | | |
| Example | Anionic | −21 | Phosphoric | Hydrogen | — | — | Aqueous | 4.0 | 80 |
| A8 | colloidal | | acid | peroxide | | | ammonia | | |
| | silica | | (1.7) | (0.03) | | | | | |
| | (15.0) | | | | | | | | |
| Example | Anionic | −10 | Phosphoric | Hydrogen | 1,2,4- | — | — | 2.5 | 110 |
| A9 | colloidal | | acid | peroxide | Triazole | | | | |
| | silica | | (1.7) | (0.03) | (3.0) | | | | |
| | (15.0) | | | | | | | | |
| Example | Anionic | −10 | Phosphoric | Hydrogen | 1,2,4- | 5-Methyl(-1H-) | — | 2.5 | 120 |
| A10 | colloidal | | acid | peroxide | Triazole | benzotriazole | | | |
| | silica | | (1.7) | (0.03) | (3.0) | (0.3) | | | |
| | (15.0) | | | | | | | | |
| Example | Anionic | −28 | Phosphoric | Hydrogen | 1,2,4- | 5-Methyl(-1H-) | Aqueous | 6.0 | 40 |
| A11 | colloidal | | acid | peroxide | Triazole | benzotriazole | ammonia | | |
| | silica | | (1.7) | (0.03) | (3.0) | (0.3) | | | |
| | (15.0) | | | | | | | | |
| Example | Anionic | −25 | Phosphoric | Hydrogen | 1,2,4- | 5-Methyl(-1H-) | Aqueous | 5.0 | 80 |
| A12 | colloidal | | acid | peroxide | Triazole | benzotriazole | ammonia | | |
| | silica | | (1.7) | (0.03) | (3.0) | (0.3) | | | |
| | (15.0) | | | | | | | | |
| Example | Anionic | −21 | Phosphoric | Hydrogen | 1,2,4- | 5-Methyl(-1H-) | Aqueous | 4.0 | 120 |
| A13 | colloidal | | acid | peroxide | Triazole | benzotriazole | ammonia | | |
| | silica | | (1.7) | (0.03) | (3.0) | (0.3) | | | |
| | (15.0) | | | | | | | | |

TABLE 2

| | | Zeta | | | | | | | |
|---|---|---|---|---|---|---|---|---|---|
| | | potential | | | Triazole- | Triazole- | | | Ruthe- |
| | Polishing | of | | | based | based | | | nium |
| | particles | polishing | | Oxidizing | compound | compound | | | polishing |
| | (% by | particles | Acid | agent | (1) (% by | (2) (% by | pH | | rate |
| No. | mass) | (mV) | (% by mass) | (% by mass) | mass) | mass) | adjuster | pH | (Å/min) |
| Compar- | Cationic | +5 | Phosphoric | Hydrogen | — | — | Aqueous | 3.0 | 20 |
| ative | colloidal | | acid | peroxide | | | ammonia | | |
| Example | silica | | (1.7) | (0.03) | | | | | |
| A1 | (15.0) | | | | | | | | |
| Compar- | Anionic | −15 | Malic acid | Hydrogen | — | — | Aqueous | 3.0 | 15 |
| ative | colloidal | | (1.7) | peroxide | | | ammonia | | |
| Example | silica | | | (0.03) | | | | | |
| A2 | (15.0) | | | | | | | | |
| Compar- | Anionic | −30 | Phosphoric | Hydrogen | — | — | Aqueous | 7.0 | 20 |
| ative | colloidal | | acid | peroxide | | | ammonia | | |
| Example | silica | | (1.7) | (0.03) | | | | | |
| A3 | (15.0) | | | | | | | | |
| Compar- | Anionic | −15 | Phosphoric | — | — | — | Aqueous | 3.0 | 1 |
| ative | colloidal | | acid | | | | ammonia | | |
| Example | silica | | (1.7) | | | | | | |
| A4 | (15.0) | | | | | | | | |
| Compar- | Cationic | +5 | Phosphoric | Hydrogen | 1,2,4- | 5-Methyl(-1H-) | — | 2.5 | 30 |
| ative | colloidal | | acid | peroxide | Triazole | benzotriazole | | | |
| Example | silica | | (1.7) | (0.03) | (3.0) | (0.3) | | | |
| A5 | (15.0) | | | | | | | | |
| Compar- | Cationic | +10 | Phosphoric | Hydrogen | 1,2,4- | 5-Methyl(-1H-) | — | 2.5 | 20 |
| ative | colloidal | | acid | peroxide | Triazole | benzotriazole | | | |
| Example | silica | | (1.7) | (0.03) | (3.0) | (0.3) | | | |
| A6 | (15.0) | | | | | | | | |
| Compar- | Cationic | +10 | Malic acid | Hydrogen | 1,2,4- | 5-Methyl(-1H-) | — | 2.5 | 8 |
| ative | colloidal | | (1.7) | peroxide | Triazole | benzotriazole | | | |
| Example | silica | | | (0.03) | (3.0) | (0.3) | | | |
| A7 | (15.0) | | | | | | | | |

TABLE 3

| | | Zeta | | | | Second | | | Corro- | | |
|---|---|---|---|---|---|---|---|---|---|---|---|
| | | potential | | | First | anti- | | | sion | Ruthe- | |
| | | of | | Oxidizing | anti- | corrosion | | | poten- | nium | |
| | Polishing | polishing | | agent | corrosion | agent | | | tial | polishing | |
| | particles | particles | Acid | (% by | agent | (% by | Additives | | [Ru-Cu] | rate | Galvanic |
| No. | (% by mass) | (mV) | (% by mass) | mass) | (% by mass) | mass) | (% by mass) | pH | (mV) | (Å/min) | corrosion |
| Example | Anionic | −21 | Phosphoric | Hydrogen | 5-Methyl(-1H-) | 1,2,4- | — | 4.0 | −280 | 51 | A |
| B1 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Phosphoric | Hydrogen | 5-Methyl(-1H-) | 1,2,4- | — | 5.0 | −200 | 45 | A |
| B2 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −28 | Phosphoric | Hydrogen | 5-Methyl(-1H-) | 1,2,4- | — | 6.0 | −140 | 38 | A |
| B3 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −24 | Phosphoric | Hydrogen | 5-Methyl(-1H-) | — | — | 5.0 | −240 | 43 | A |
| B4 | colloidal | | acid | peroxide | benzotriazole | | | | | | |
| | silica | | (0.4) | (0.03) | (0.5) | | | | | | |
| | (15.0) | | | | | | | | | | |
| Example | Anionic | −28 | Phosphoric | Hydrogen | 5-Methyl(-1H-) | — | — | 6.0 | −190 | 35 | A |
| B5 | colloidal | | acid | peroxide | benzotriazole | | | | | | |
| | silica | | (0.4) | (0.03) | (0.5) | | | | | | |
| | (15.0) | | | | | | | | | | |
| Example | Anionic | −26 | Phosphoric | Hydrogen | Benzotriazole | 1,2,4- | — | 5.0 | −260 | 40 | A |
| B6 | colloidal | | acid | peroxide | (1.0) | Triazole | | | | | |
| | silica | | (0.4) | (0.03) | | (3.0) | | | | | |
| | (15.0) | | | | | | | | | | |
| Example | Anionic | −25 | Phosphoric | Hydrogen | Benzotriazole | — | — | 5.0 | −280 | 37 | A |
| B7 | colloidal | | acid | peroxide | (1.0) | | | | | | |
| | silica | | (0.4) | (0.03) | | | | | | | |
| | (15.0) | | | | | | | | | | |
| Example | Anionic | −20 | Phosphoric | Hydrogen | 5-Methyl(-1H-) | 1,2,4- | Tetraphenyl- | 4.0 | −300 | 52 | A |
| B8 | colloidal | | acid | peroxide | benzotriazole | Triazole | phosphonium | | | | |
| | silica | | (0.4) | (0.03) | (0.5) | (3.0) | bromide | | | | |
| | (15.0) | | | | | | (0.005) | | | | |
| Example | Anionic | −24 | Phosphoric | Hydrogen | 5-Methyl(-1H-) | 1,2,4- | Tetraphenyl- | 5.0 | −220 | 47 | A |
| B9 | colloidal | | acid | peroxide | benzotriazole | Triazole | phosphonium | | | | |
| | silica | | (0.4) | (0.03) | (0.5) | (3.0) | bromide | | | | |
| | (15.0) | | | | | | (0.005) | | | | |
| Example | Anionic | −29 | Phosphoric | Hydrogen | 5-Methyl(-1H-) | 1,2,4- | Tetraphenyl- | 6.0 | −170 | 40 | A |
| B10 | colloidal | | acid | peroxide | benzotriazole | Triazole | phosphonium | | | | |
| | silica | | (0.4) | (0.03) | (0.5) | (3.0) | bromide | | | | |
| | (15.0) | | | | | | (0.005) | | | | |
| Example | Anionic | −25 | Phosphoric | Hydrogen | 5-Methyl(-1H-) | — | Tetraphenyl- | 5.0 | −250 | 45 | A |
| B11 | colloidal | | acid | peroxide | benzotriazole | | phosphonium | | | | |
| | silica | | (0.4) | (0.03) | (0.5) | | bromide | | | | |
| | (15.0) | | | | | | (0.005) | | | | |
| Example | Anionic | −20 | Nitric | Hydrogen | 5-Methyl(-1H-) | 1,2,4- | Tetraphenyl- | 4.0 | −280 | 35 | A |
| B12 | colloidal | | acid | peroxide | benzotriazole | Triazole | phosphonium | | | | |
| | silica | | (0.4) | (0.03) | (0.5) | (3.0) | bromide | | | | |
| | (15.0) | | | | | | (0.005) | | | | |
| Example | Anionic | −10 | Phosphoric | Hydrogen | — | 1,2,4- | — | 2.5 | −1200 | 110 | B |
| B13 | colloidal | | acid | peroxide | | Triazole | | | | | |
| | silica | | (1.7) | (0.03) | | (3.0) | | | | | |
| | (15.0) | | | | | | | | | | |
| Example | Anionic | −21 | Phosphoric | Hydrogen | — | — | — | 4.0 | −850 | 80 | B |
| B14 | colloidal | | acid | peroxide | | | | | | | |
| | silica | | (1.7) | (0.03) | | | | | | | |
| | (15.0) | | | | | | | | | | |
| Compa- | Anionic | −32 | Phosphoric | Hydrogen | 5-Methyl(-1H-) | 1,2,4- | — | 7.0 | −150 | 15 | A |
| rative | colloidal | | acid | peroxide | benzotriazole | Triazole | | | | | |
| Example | silica | | (0.4) | (0.03) | (0.3) | (3.0) | | | | | |
| B1 | (15.0) | | | | | | | | | | |
| Compar- | Cationic | +5 | Phosphoric | Hydrogen | 5-Methyl(-1H-) | 1,2,4- | — | 4.0 | −250 | 7 | A |
| ative | colloidal | | acid | peroxide | benzotriazole | Triazole | | | | | |
| Example | silica | | (0.4) | (0.03) | (0.5) | (3.0) | | | | | |
| B2 | (15.0) | | | | | | | | | | |

TABLE 4

| | | Zeta | | | | Second | | | | | |
|---|---|---|---|---|---|---|---|---|---|---|---|
| | | potential | | | First | anti- | | | | Ruthe- | |
| | Polishing | of | | Oxidizing | anti- | corrosion | | | Corrosion | nium | |
| | particles | polishing | Acid | agent | corrosion | agent | Additives | | potential | polishing | |
| | (% by | particles | (% by | (% by | agent | (% by | (% by | | [Ru-Cu] | rate | Galvanic |
| No. | mass) | (mV) | mass) | mass) | (% by mass) | mass) | mass) | pH | (mV) | (Å/min) | corrosion |
| Example | Anionic | −25 | Glycolic | Hydrogen | 5-Methyl(-1H-) | 1,2,4- | — | 5.0 | −100 | 37 | A |
| C1 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Lactic | Hydrogen | 5-Methyl(-1H-) | 1,2,4- | | | | | |
| C2 | colloidal | | | | benzotriazole | Triazole | — | 5.0 | −110 | 45 | A |
| | silica | | acid | peroxide | (0.5) | (3.0) | | | | | |
| | (15.0) | | (0.4) | (0.03) | | | | | | | |
| Example | Anionic | −25 | Fumaric | Hydrogen | 5-Methyl(-1H-) | 1,2,4- | — | 5.0 | −90 | 43 | A |
| C3 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Itaconic | Hydrogen | 5-Methyl(-1H-) | 1,2,4- | — | 5.0 | −170 | 38 | A |
| C4 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Maleic | Hydrogen | 5-Methyl(-1H-) | 1,2,4- | — | 5.0 | −120 | 41 | A |
| C5 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Glycine | Hydrogen | 5-Methyl(-1H-) | 1,2,4- | — | 5.0 | −150 | 46 | A |
| C6 | colloidal | | (0.4) | peroxide | benzotriazole | Triazole | | | | | |
| | silica | | | (0.03) | (0.5) | (3.0) | | | | | |
| | (15.0) | | | | | | | | | | |
| Example | Anionic | −25 | Alanine | Hydrogen | 5-Methyl(-1H-) | 1,2,4- | — | 5.0 | −50 | 55 | A |
| C7 | colloidal | | (0.4) | peroxide | benzotriazole | Triazole | | | | | |
| | silica | | | (0.03) | (0.5) | (3.0) | | | | | |
| | (15.0) | | | | | | | | | | |
| Example | Anionic | −25 | Salicylic | Hydrogen | 5-Methyl(-1H-) | 1,2,4- | — | 5.0 | −170 | 43 | A |
| C8 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Propionic | Hydrogen | 5-Methyl(-1H-) | 1,2,4- | — | 5.0 | −160 | 49 | A |
| C9 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Example | Anionic | −25 | Acetic | Hydrogen | 5-Methyl(-1H-) | 1,2,4- | — | 5.0 | −190 | 55 | A |
| C10 | colloidal | | acid | peroxide | benzotriazole | Triazole | | | | | |
| | silica | | (0.4) | (0.03) | (0.5) | (3.0) | | | | | |
| | (15.0) | | | | | | | | | | |
| Compa- | Anionic | −25 | Malic | Hydrogen | 5-Methyl(-1H-) | 1,2,4- | — | 5.0 | −180 | 10 | A |
| rative | colloidal | | acid | peroxide | benzotriazole | Triazole | | | | | |
| Example | silica | | (0.4) | (0.03) | (0.5) | (3.0) | | | | | |
| C1 | (15.0) | | | | | | | | | | |
| Compa- | Anionic | −25 | Citric | Hydrogen | 5-Methyl(-1H-) | 1,2,4- | — | 5.0 | −160 | 15 | A |
| rative | colloidal | | acid | peroxide | benzotriazole | Triazole | | | | | |
| Example | silica | | (0.4) | (0.03) | (0.5) | (3.0) | | | | | |
| C2 | (15.0) | | | | | | | | | | |
| Compa- | Anionic | −25 | Tartaric | Hydrogen | 5-Methyl(-1H-) | 1,2,4- | — | 5.0 | −120 | 15 | A |
| rative | colloidal | | acid | peroxide | benzotriazole | Triazole | | | | | |
| Example | silica | | (0.4) | (0.03) | (0.5) | (3.0) | | | | | |
| C3 | (15.0) | | | | | | | | | | |

Hereinafter, the results shown in Table 1 to Table 4 will be described in detail.

From the results of Examples A1 to A13, it turns out that the polishing rate of the ruthenium-based metal is increased when the CMP polishing liquids comprising the polishing particles having a negative zeta potential in the CMP polishing liquid, the specific acid component, the oxidizing agent, and water and having a pH of less than 7.0 are used.

In particular, according to Examples A1 to A3, it turns out that the polishing rate of ruthenium is higher as the content of the polishing particles having a negative zeta potential in the CMP polishing liquid is larger.

According to Examples A3 to A6, it turns out that the content of the acid component is correlated with the polishing rate of ruthenium. In comparison of Examples A3 to A6, the polishing rate of ruthenium was the largest in the CMP polishing liquid comprising 1.7% by mass of phosphoric acid.

According to Example A7, it turns out that a favorable polishing rate of ruthenium is obtained even by varying the type of the acid component.

According to Examples A9 to A13, it turns out that the polishing rate of ruthenium is remarkably increased by use of a triazole-based compound (particularly, use of 1,2,4-triazole in combination with 5-methyl(-1H-)benzotriazole).

According to Examples A3, A8, and A10 to A13, it turns out that the polishing rate of ruthenium is the largest at a pH of 1.5 to 4.0.

Examples B1 to B3 show the results of evaluation on the polishing rate of ruthenium and the galvanic corrosion of the polishing liquids comprising 5-methyl(-1H-)benzotriazole and 1,2,4-triazole as anti-corrosion agents. From these results, it turns out that the galvanic corrosion of the wiring metal can be prevented while the polishing rate of ruthenium is kept high when the difference in corrosion potential is small.

Examples B4 and B5 show the results of evaluation on the polishing rate of ruthenium and the galvanic corrosion of the polishing liquids comprising only 5-methyl(-1H-)benzotriazole as the anti-corrosion agent. Also in the cases where the polishing liquids comprise only 5-methyl(-1H-)benzotriazole, it turns out that the galvanic corrosion of the wiring metal can be prevented while the polishing rate of ruthenium is kept high when the difference in corrosion potential is small.

From the results of Examples B6 and B7, it turns out that the galvanic corrosion of the wiring metal can be prevented while the polishing rate of ruthenium is kept high also in the cases where benzotriazole is used as the anti-corrosion agent.

The polishing liquids in Examples B8 to B11 have compositions comprising the polishing liquids in Examples B1 to B4 and further comprising tetraphenylphosphonium bromide as an additive. It turns out that the polishing rate of ruthenium is further increased and the galvanic corrosion of the wiring metal can be prevented when the polishing liquids comprise such an additive.

From the results of Example B12, it turns out that the galvanic corrosion of the wiring metal can be prevented while the polishing rate of ruthenium is kept high also in the cases where nitric acid is used as the acid component.

In Examples B13 and B14, it turns out that the polishing rate of the ruthenium-based metal is high although galvanic corrosion is generated.

From the results of Examples C1 to C10, it turns out that the galvanic corrosion of the wiring metal can be prevented while the polishing rate of ruthenium is kept high by use of a variety of acid components specified in the present application.

From the results of Comparative Example A3 and Comparative Example B1, it turns out that the polishing rate of ruthenium is reduced at a pH of 7.0. From the results of Comparative Examples A1 and A5 to A7 and Comparative Example B2, it turns out that the polishing rate of ruthenium is reduced when the zeta potential of the polishing particles is positive. From the results of Comparative Examples A2 and A7 and Comparative Examples C1 to C3, it turns out that the polishing rate of ruthenium is reduced when the acid component specified in the present application is not used. From the result of Comparative Example A4, it turns out that the polishing rate of ruthenium is reduced when the oxidizing agent is not used.

From the above results, it turns out that the polishing rate of the ruthenium-based metal is increased in all of Examples. Moreover, it is verified in Examples B1 to B12 and Examples C1 to C10 that the galvanic corrosion of the wiring metal can be prevented while the polishing rate of the ruthenium-based metal is kept high.

### INDUSTRIAL APPLICABILITY

The present invention can increase the polishing rate of the ruthenium-based metal, compared to the cases where the conventional CMP polishing liquid is used. Moreover, one embodiment of the present invention can provide a CMP polishing liquid which can increase the polishing rate of the ruthenium-based metal and prevent the galvanic corrosion of the wiring metal compared to the cases where the conventional CMP polishing liquid is used, and a polishing method using the same.

### REFERENCE SIGNS LIST

1, 11 . . . insulating material, 2 . . . trench portions (depressed portions), 3, 14 . . . wiring metal, 4, 12 . . . barrier metal, 5, 15 . . . seed layer, 6 . . . metal (barrier metal or seed layer), 7 . . . hollows (voids), 13 . . . ruthenium-based metal.

1. A CMP polishing liquid for polishing a ruthenium-based metal, comprising:
polishing particles;
an acid component;
an oxidizing agent; and
water,
wherein the acid component contains at least one selected from the group consisting of inorganic acids, monocarboxylic acids, carboxylic acids having a plurality of carboxyl groups and having no hydroxyl group, and salts thereof,
the polishing particles have a negative zeta potential in the CMP polishing liquid, and
a pH of the CMP polishing liquid is less than 7.0.

2. The CMP polishing liquid according to claim 1, further comprising a triazole-based compound.

3. The CMP polishing liquid according to claim 1, wherein the pH of the CMP polishing liquid is 1.0 to 6.0.

4. A CMP polishing liquid for polishing a base having a ruthenium-based metal and a wiring metal, comprising:
polishing particles;
an acid component;
an oxidizing agent; and
water,
wherein the acid component contains at least one selected from the group consisting of inorganic acids, monocarboxylic acids, carboxylic acids having a plurality of carboxyl groups and having no hydroxyl group, and salts thereof,
the polishing particles have a negative zeta potential in the CMP polishing liquid,
a difference A−B between a corrosion potential A of a ruthenium-based metal and a corrosion potential B of a wiring metal in the CMP polishing liquid is −500 to 0 mV, and
a pH of the CMP polishing liquid is less than 7.0.

5. The CMP polishing liquid according to claim 4, further comprising a first anti-corrosion agent represented by the following general formula (I). 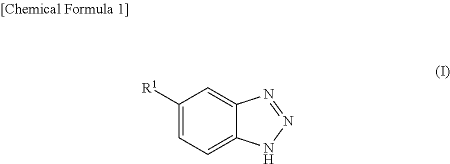
[In formula (I), R¹ represents a hydrogen atom or an alkyl group having 1 to 3 carbon atoms.]

6. The CMP polishing liquid according to claim 5, further comprising a second anti-corrosion agent.

7. The CMP polishing liquid according to claim 6, wherein the second anti-corrosion agent is a triazole-based compound (excluding the first anti-corrosion agent).

8. The CMP polishing liquid according to claim 4, further comprising a quaternary phosphonium salt.

9. The CMP polishing liquid according to claim 8, wherein the quaternary phosphonium salt is at least one selected from the group consisting of triaryl phosphonium salts and tetraaryl phosphonium salts.

10. The CMP polishing liquid according to claim 8, wherein the quaternary phosphonium salt is a compound represented by the following general formula (II). 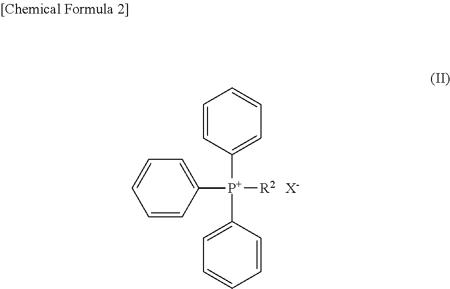
[In formula (II), benzene rings each may have a substituent; R² represents an optionally substituted alkyl group or aryl group; and X⁻ represents an anion.]

11. The CMP polishing liquid according claim 4, wherein the pH of the CMP polishing liquid is 3.5 or more.

12. The CMP polishing liquid according to claim 1, wherein the acid component is at least one selected from the group consisting of nitric acid, phosphoric acid, glycolic acid, lactic acid, glycine, alanine, salicylic acid, acetic acid, propionic acid, fumaric acid, itaconic acid, maleic acid, and salts thereof.

13. The CMP polishing liquid according to claim 1,
wherein the CMP polishing liquid is separately stored in a form of a first liquid and a second liquid,
the first liquid contains the polishing particles and the acid component, and
the second liquid contains the oxidizing agent.

14. A polishing method, comprising a step of polishing a base having a ruthenium-based metal using the CMP polishing liquid according to claim 1 to remove at least part of the ruthenium-based metal.

15. The polishing method according to claim 14, wherein the base further has a wiring metal.

16. The polishing method according to claim 15, wherein the wiring metal is a copper-based metal.

17. The polishing method according to claim 14, further comprising a step of forming a ruthenium-based metal on a base by a formation method other than a physical vapor deposition method to prepare a base having a ruthenium-based metal.

18. The polishing method according to claim 17, wherein the formation method is at least one selected from the group consisting of chemical vapor deposition methods and atomic layer deposition methods.

19. The CMP polishing liquid according to claim 4, wherein the acid component is at least one selected from the group consisting of nitric acid, phosphoric acid, glycolic acid, lactic acid, glycine, alanine, salicylic acid, acetic acid, propionic acid, fumaric acid, itaconic acid, maleic acid, and salts thereof.

20. The CMP polishing liquid according to claim 4,
wherein the CMP polishing liquid is separately stored in a form of a first liquid and a second liquid,
the first liquid contains the polishing particles and the acid component, and
the second liquid contains the oxidizing agent.

21. A polishing method, comprising a step of polishing a base having a ruthenium-based metal using the CMP polishing liquid according to claim 4 to remove at least part of the ruthenium-based metal.

22. The polishing method according to claim 21, wherein the base further has a wiring metal.

23. The polishing method according to claim 22, wherein the wiring metal is a copper-based metal.

24. The polishing method according to claim 21, further comprising a step of forming a ruthenium-based metal on a base by a formation method other than a physical vapor deposition method to prepare a base having a ruthenium-based metal.

25. The polishing method according to claim 24, wherein the formation method is at least one selected from the group consisting of chemical vapor deposition methods and atomic layer deposition methods.
